(19) United States
(12) Patent Application Publication
(10) Pub. No.: US 2019/0369494 A1
(43) Pub. Date: Dec. 5, 2019

(54) INITIATOR BLENDS AND PHOTOCURABLE COMPOSITIONS CONTAINING SUCH INITIATOR BLENDS USEFUL FOR 3D PRINTING

(71) Applicant: Arkemea Inc., King of Prussia, PA (US)

(72) Inventors: Sumeet JAIN, Chester Springs, PA (US); Mary Elizabeth SULLIVAN MALERVY, Downingtown, PA (US); Marina DESPOTOPOULOU, Havertown, PA (US); Michael B. ABRAMS, Bala Cynwyd, PA (US); Leonard H. PALYS, Downingtown, PA (US)

(21) Appl. No.: 16/465,179

(22) PCT Filed: Dec. 1, 2017
(86) PCT No.: PCT/US2017/064214

§ 371 Date: May 30, 2019

Related U.S. Application Data
(60) Provisional application No. 62/429,975, filed on Dec. 5, 2016.

(51) Int. Cl. G03F 7/031; G03F 7/00; G03F 7/038; B29C 64/129

(52) U.S. Cl. CPC G03F 7/031; G03F 7/0037; B33Y 70/00; B29C 64/129; G03F 7/0381

(57) ABSTRACT

Photocurable compositions useful in the fabrication of 3D printed articles are formulated to contain a) at least one of a photoinitiator or a photo-releasable base and b) at least one t-amyl peroxide, in addition to at least one photocurable compound.

### FIELD OF THE INVENTION

The present invention pertains to initiator systems useful for curing photocurable compositions, such as photocurable compositions comprising one or more ethylenically unsaturated compounds and photocurable compositions useful as resins in 3D printing applications.

### BACKGROUND OF THE RELATED ART

In recent years, there has been significant interest in developing resin compositions for three-dimensional (3D) printing applications capable of being cured by photoinitiated processes wherein the resin composition contains one or more photocurable compounds (monomers and/or oligomers), where curing is initiated by exposure to radiation such as ultraviolet radiation. Photocurable resin compositions of this type ideally possess certain attributes such as, for example, good storage or shelf-life stability. That is, they should not undergo a significant amount of reaction or curing when stored over an extended period of time at room temperature in the absence of radiation effective to initiate reaction of the photocurable compound(s) present. At the same time, once activated by exposure to suitable radiation the photocurable resin compositions (which are typically liquid in form at room temperature) should rapidly cure (react) to provide a dimensionally stable article (such as a coating or layer). The resulting cured article should advantageously have high optical clarity (in the absence of opaque fillers, pigments and the like), high thermal stability (i.e., resistance to melting or deformation when heated), physical properties sufficient to meet the needs of the intended use of the cured article, and little or no yellowing.

To date, however, it has proven challenging to formulate photocurable resin compositions having such characteristics.

Examples of known photocurable resin compositions and methods of using such compositions, particularly in 3D printing applications, are described in the following publications:

U.S. Pat. No. 9,205,601 discloses a method of forming a three-dimensional object, comprising providing a carrier and an optically transparent member having a build surface, the carrier and the build surface defining a build region there between; filling the build region with a polymerizable liquid; irradiating the build region through the optically transparent member to form a solid polymer from the polymerizable liquid while concurrently advancing the carrier away from the build surface to form the three-dimensional object from the solid polymer, while also concurrently: (i) continuously maintaining a dead zone of polymerizable liquid in contact with the build surface, and (ii) continuously maintaining a gradient of polymerization zone between the dead zone and the solid polymer and in contact with each thereof, the gradient of polymerization zone comprising the polymerizable liquid in partially cured form.

WO 2015/105762 discloses a process for the production of a three-dimensional object of a high performance polymer (e.g., a liquid crystal thermoset polymer) carried out by (a) providing a radiation source (e.g., a carbon dioxide laser) and a carrier for supporting a three dimensional object during production thereof, the radiation source and the carrier defining a build region; (b) providing a precursor of a high performance polymer to the build region in liquid or solid form; (c) cross-linking (e.g., thermally crosslinking) the precursor in the build region to produce a solid polymerized region of the polymer; (d) advancing said carrier with said polymerized region adhered thereto away from said build region to create a subsequent build region between the polymerized region and said radiation source; and (e) repeating steps (b) through (d) until production of the three-dimensional object is completed.

WO 2015/142546 discloses a method of forming a three-dimensional object, which is carried out by: (a) providing a carrier and an optically transparent member having a build surface, with the carrier and the build surface defining a build region there between; (b) filling the build region with a polymerizable liquid; (c) irradiating the build region with light through the optically transparent member to form a solid polymer from the polymerizable liquid; and (d) advancing the carrier away from the build surface to form the three-dimensional object from the solid polymer, (e) wherein the carrier has at least one channel formed therein, the method further including supplying pressurized gas into the build region through the at least one channel during at least a portion of the filling, irradiating and/or advancing steps.

WO 2015/164234 discloses a method of forming a three-dimensional object which is carried out by: providing a carrier and a pool of immiscible liquid, the pool having a liquid build surface, the carrier and the liquid build surface defining a build region there between; filling the build region with a polymerizable liquid, wherein the immiscible liquid is immiscible with the polymerizable liquid; irradiating the build region through at least a portion of the pool of immiscible liquid to form a solid polymer from the polymerizable liquid and advancing the carrier away from the liquid build surface to form the three-dimensional object comprised of the solid polymer from the polymerizable liquid. Optionally, the method is carried out while also continuously maintaining a gradient of polymerization zone between the liquid build surface and the solid polymer and in contact with each thereof, the gradient of polymerization zone comprising the polymerizable liquid in partially cured form.

WO 2015/195909 discloses a method of forming a three-dimensional object which includes: providing a carrier and an optically transparent member having a build surface, the carrier and the build surface defining a build region there between, filling the build region with a polymerizable liquid, irradiating the build region with light through the optically transparent member to form a solid polymer from the polymerizable liquid, and advancing the carrier away from the build surface to form the three-dimensional object from the solid polymer.

US 2016/0136889 discloses a method of forming a three-dimensional object which is carried out by: (a) providing a carrier and an optically transparent member having a build surface, the carrier and the build surface defining a build region there between; (b) filling the build region with a polymerizable liquid, the polymerizable liquid including a mixture of (i) a light polymerizable liquid first component, and (ii) a second solidifiable component that is different from the first component; (c) irradiating the build region with light through the optically transparent member to form a solid polymer scaffold from the first component and also advancing the carrier away from the build surface to form a three-dimensional intermediate having the same shape as, or a shape to be imparted to, the three-dimensional object, and containing the second solidifiable component carried in the scaffold in unsolidified and/or uncured form; and (d) concurrently with or subsequent to the irradiating step, solidifying and/or curing the second solidifiable component in the three-dimensional intermediate to form the three-dimensional object.

US 2011/0190412 discloses photolatent amidine bases for redox curing of radically curable formulations, such as a composition comprising (a1) a photolatent amidine base; or (a2) a photolatent amine base; or (a3) a mixture of (a1) and (a2); and (b) a radically polymerizable compound; and (c) a free radical initiator capable of being reduced by amines and/or amidines, in particular a peroxide.

### SUMMARY OF THE INVENTION

It has now been discovered that the use of photoinitiators and/or photo-releasable bases in combination with one or more t-amyl peroxides in compositions containing photocurable compounds (e.g., ethylenically unsaturated monomers and/or oligomers such as (meth)acrylate-functionalized monomers and/or oligomers) in a 3D printing process unexpectedly provides improved thermally stable, heat resistant structures with good clarity and little or no yellowing of the final printed article. The presence oft-amyl peroxide in such photocurable compositions, when decomposed (initiated) during photocuring as a result of the presence of photo-releasable base and/or in a post-photocure heating step, unexpectedly facilitates the production of a stronger 3D-printed article, with little to no detrimental changes to the original shape or color of the 3D-printed article (as compared to its shape and color prior to the post-photocure step).

The use of photoinitiators by themselves in photocurable compositions employed as 3D printing resins (i.e., where the photocurable compositions do not contain any other type of free radical initiator other than photoinitiator) typically does not readily result in a finished 3D printed article having the physical properties (e.g., hardness, modulus, impact strength) generally required for both clear and opaque articles (wherein an opaque article contains a white or colored particulate filler, for example).

It has now been found that by using a t-amyl peroxide in combination with a photoinitiator, additional crosslinking of a photocurable composition, following an initial photocuring step, may be attained by utilizing a post-photocuring step wherein a 3D printed article is heated (for example in an oven). In another variation of the present invention, a t-amyl peroxide may be used in combination with a photo-releasable base, such as a photo-releasable amine, which is converted into a base capable of participating in a redox reaction with the t-amyl peroxide, thereby accelerating its decomposition rate and facilitating or enhancing the desired curing of the photocurable compound(s).

In yet another variation of the present invention, a t-amyl peroxide may be used in combination with a non t-amyl peroxide. In yet another variation of the present invention, a t-amyl type peroxide having at least one free-radical polymerizable unsaturated group may be used in combination with a non t-amylperoxide also having at least one free-radical polymerizable unsaturated group. In yet another variation of the present invention, the t-amyl type peroxides which are branched polyoligomers comprising at least three organic peroxide branches, are used.

By following such a procedure using such formulations, a finished 3D-printed article may be obtained with improved physical properties, but little or no change in color and/or clarity.

### DETAILED DESCRIPTION OF THE INVENTION

In accordance with the present invention, a combination of at least one t-amyl peroxide and at least one photonitiator and/or at least one photo-releasable base is used to cure a composition containing one or more photocurable compounds such as free radically-curable unsaturated compounds including mono- and/or multi-functional acrylic compounds, methacrylic compounds, styrenic compounds, unsaturated polyesters, unsaturated polyurethanes, allylic compounds, maleimide compounds and vinylic compounds and combinations thereof. Such compositions may be free of any fillers or may contain various opaque fillers (such as titanium dioxide, to provide whitened cured articles). The photocurable composition may be fed into a 3D printer and used as a resin to print a three-dimensional article which is initially cured using radiation such as ultraviolet radiation or laser light. The resulting printed article may then be post-cured to thermally activate the peroxide(s). That is, the printed article may be heated to a temperature and for a time effective to cause the peroxide(s) to decompose and generate free radical species, which assist in further curing (crosslinking) of the printed article. It may also be possible to achieve such enhanced curing/crosslinking of the printed article by including one or more photo-releasable bases in the photocurable composition, which may function as accelerators for peroxide decomposition once subjected to radiation effective to convert the photo-releasable base into a free base such as a tertiary amine.

t-Amyl Peroxides

According to various embodiments, a composition in accordance with the present invention may comprise one or more t-amyl peroxides. As used herein, the term “t-amyl peroxide” refers to an organic compound comprising at least one t-amyl [—C(CH₃)₂(CH₂CH₃)] moiety and at least one peroxy (—O—O—) moiety.

Suitable t-amyl peroxides may, for example, be selected from the group consisting of hemi-peroxyketals, diperoxyketals, peroxyesters, dialkyl peroxides, hydroperoxides, monoperoxycarbonates and combinations thereof (with the understanding that all such compounds contain at least one t-amyl group). However, in one embodiment, a composition in accordance with the present invention contains at least one t-amyl peroxide other than a t-amyl hydroperoxide. In another embodiment, the composition does not contain any t-amyl hydroperoxide. It may be advantageous to employ t-amyl peroxides having a one hour half-life of at least about 85° C., at least 90° C., at least 92° C., at least 95° C. or at least 99° C., as measured in accordance with the procedures described below. Exemplary t-amyl peroxides useful in the present invention include, but are not limited to, 1-t-amylperoxy-1-methoxy cyclohexane, 1,1-di-t-amylperoxy cyclohexane, 1,1-di-t-amylperoxy-3,3,5-trimethyl cyclohexane, 2,2-di-t-amyl peroxy butane, 2,2-di-t-amylperoxypropane, OO-t-amyl-O-(2-ethylhexyl) monoperoxycarbonate, OO-t-amyl-O-(2-isopropyl) monoperoxycarbonate, t-amyl peroxyacetate, t-amylperoxy-3,5,5-trimethylhexanoate, di-t-amyl peroxide, t-amyl hydroperoxide (although in one embodiment, the composition is free of t-amyl hydroperoxide) and combinations thereof.

Other exemplary t-amyl type peroxides used in the practice of this invention include an organic peroxide branched oligomer comprising at least three peroxide groups. One such t-amyl peroxide is exemplified in the structure below which is a preferred polyether poly-t-amyl

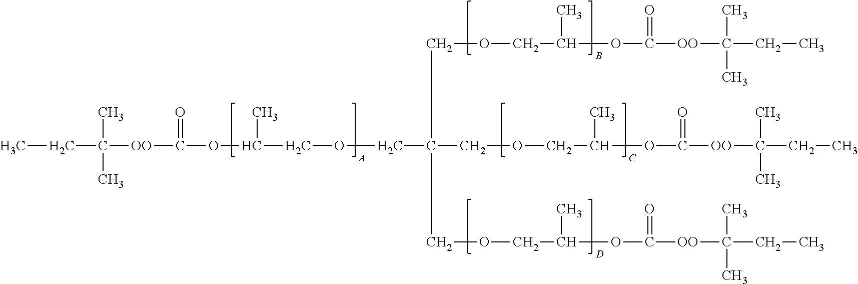

peroxycarbonate, where the sum of A, B, C and D is 4 or more, and preferably 6 or 7.
The organic peroxide may comprise a compound represented by structure A:

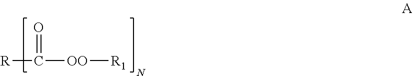

wherein N is an integer from 3 to 4; R₁ is each independently a tertiary-alkyl radical group having from 4 to 10 carbons; and R is a polyether compound having three to four branched alkyloxy radical groups. The branched alkyloxy radical groups of the polyether compound R may be selected from CH₃—C(CH₂—O—)₃, C(CH₂—O—)₄, and R may have a structure according to structure B or structure C:

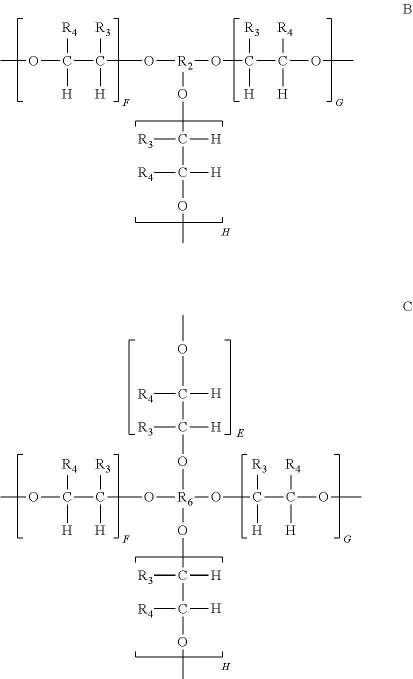

wherein R₂ is a branched trifunctional alkyl radical having the structure CH₃—C(CH₂—)₃, or a branched trifunctional alkyl radical having the structure

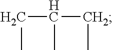

R₆ is a branched tetrafunctional alkyl radical having the structure C(CH₂—)₄; R₃ and R₄ are independently selected from hydrogen and alkyl radicals containing 1 to 4 carbons; and E, F, G and H are integers from 1 to 4.

Various t-amyl type peroxides may be combined with polyoligomeric non t-amyl type peroxides, for example, polyether poly-t-butyl peroxycarbonate having a structure shown below which also is a preferred polyoligomeric peroxide, where the sum of A, B, C and D is 6 or 7.

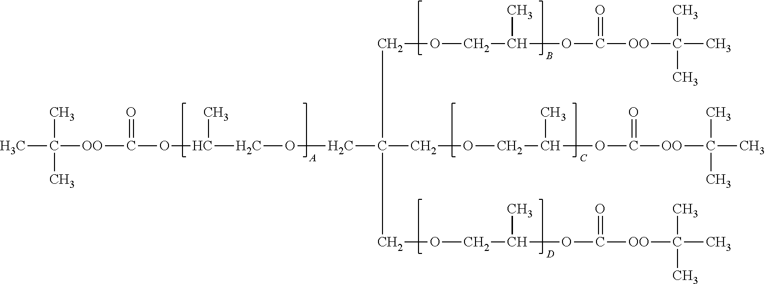

One advantage of using polyether poly-t-amyl and/or poly-t-butyl peroxycarbonate peroxides in the formulations and/or processes of the invention that they unexpectedly provide consistent crosslinking performance when curing a 3D printed article in, for example, an oven or autoclave. This is especially observed when a 3D printed article is stored for a period of days or weeks after printing and before finishing the cure. As it may take longer to print numerous articles, it may be desirable to cure them all at once. The use of these peroxide formulations provide improved adhesion and/or strength for articles that are manufactured for example, layer by layer and also to a final cure article. Furthermore, the use of free-radically polymerizable unsaturated peroxides provide this same unexpected benefit. During the 3D printing process using various UV initiators, it is believed that unsaturated peroxide may become part of a polymer chain dispersed in a polymeric network, thus unexpectedly overcoming issues of peroxide loss or migration.

One skilled in the art can then perform the curing step using known curing processes, including for example, an oven in heated atmospheric air or a heated inert gas such as nitrogen or carbon dioxide. Curing also can be done using a steam autoclave.

The use of t-amyl hemi-peroxyketals and/or t-amyl diperoxyketals in the photocurable compositions and methods of the present invention is particularly advantageous. Hemi-peroxyketals contain a single peroxy (—O—O—) group bonded to a carbon atom substituted with a non-peroxy oxygen atom (e.g., an oxygen atom that forms part of a hydroxyl or ether group), while diperoxyketals contain two peroxy groups, each of which is bonded to the same carbon atom.

The structure of one of the most preferred hemi-peroxyketals: 1-t-amylperoxy-1-methoxy-3,3,5-trimethyl cyclohexane; is provided below.

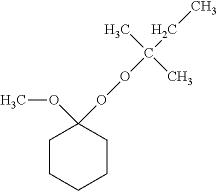

Preferred hemi-peroxyketals include, but are not limited to: I-t-amylperoxy-1-methoxy-3,3,5-trimethyl cyclohexane; 1-t-amylperoxy-1-methoxy cyclohexane and 2-methoxy-2-t-amylperoxy propane; and 2-methoxy-2-t-amylperoxy butane. Preferred diperoxyketals include, but are not limited to: 1,1-di(t-amylperoxy)-3,3,5-trimethyl cyclohexane; 1,1-di(t-amylperoxy) cyclohexane; 2,2-di(t-amylperoxy)propane; 2,2-di(t-amylperoxy)butane; n-butyl-4,4,-di(t-amylperoxy)valerate; and ethyl-3,3-di-(t-amylperoxy) butyrate.

The various exemplary t-amyl peroxides listed above can be used in combination with non t-amyl type peroxides which include but are not limited to, t-butyl type peroxides, t-hexyl type peroxides, t-heptyl and t-octyl type organic peroxides in the practice of this invention. For example, 1-t-butylperoxy-1-methoxy-3,3,5-trimethyl cyclohexane, 1-t-hexylperoxy-1-methoxy-3,3,5-trimethyl cyclohexane, 1-t-heptylperoxy-1-methoxy-3,3,5-trimethyl cyclohexane, 1-t-octylperoxy-1-methoxy-3,3,5-trimethyl cyclohexane, OO-t-butyl-O-(2-ethylhexyl) monoperoxycarbonate, OO-t-butyl-O-(2-isopropyl) monoperoxycarbonate, OO-t-octyl-O-(2-ethylhexyl) monoperoxycarbonate, OO-t-octyl-O-(2-isopropyl) monoperoxycarbonate, OO-t-hexyl-O-(2-ethylhexyl) monoperoxycarbonate, OO-t-hexyl-O-(2-isopropyl) monoperoxycarbonate, 1,1-di-t-butylperoxy-3,3,5-trimethyl cyclohexane, 1,1-di-t-octylperoxy-3,3,5-trimethyl cyclohexane, 1,1-di-t-hexylperoxy-3,3,5-trimethyl cyclohexane, 1,1-di-t-heptylperoxy-3,3,5-trimethyl cyclohexane, polyether poly(t-butyl)-peroxycarbonate, polyether poly(t-hexyl)-peroxycarbonate, polyether poly(t-heptyl)-peroxycarbonate and polyether poly(t-octyl)-peroxycarbonate.

To reduce residual photocurable compounds to very low (ppm) levels once a finished article prepared from a photocurable composition has been prepared, t-amyl monoperoxycarbonates can be employed. Suitable t-amyl monoperoxycarbonates include, but are not limited to: t-amylperoxy-2-ethylhexylmonoperoxycarbonate; and t-amylperoxyisopropyl monoperoxycarbonate. These peroxides can be used in combination with one or more of the aforementioned diperoxyketals.

Preferably, the t-amyl peroxide or t-amyl peroxides selected provide(s) a photocurable composition which is room temperature stable (e.g., sufficiently stable at 70° F. such that the photocurable composition can be safely stored for at least three months without significant change, e.g., not more than 10%, preferably not more than 5%, more preferably not more than 1%, and most preferably not more than 0.5% loss in peroxide content, based on the weight percent of photocurable composition). However, the t-amyl peroxide(s) is/are also preferably selected to provide a photocurable composition that can be further cured by heating, after an initial photocuring step, at a relatively low temperature (e.g., <200° C.), wherein such further heat curing effectively reduces the amount of unreacted monomer/oligomer in the cured article and results in a cured article having a low YID (yellowness index).

In place of a t-amyl peroxide or together with a t-amyl peroxide, the use of certain cyclic peroxides is also contemplated to be within the scope of the present invention. Such cyclic peroxides may contain diperoxyketal moieties as part of their cyclic structure, in particular, diperoxy ketal moieties corresponding to the formula —O—O—C(CH₃)(CH₂CH₃)—O—O—. An example of such a cyclic peroxide is 3,6,9-triethyl-3,6,9-trimethyl-1,4,7-triperoxonane (also known as methylethylketone peroxide trimer), which may be classified as a t-amyl peroxide since it contains both peroxy (—O—O—) groups and C(CH₃)(CH₂CH₃) groups.

One skilled in art may use the two step method described herein to identify and select preferred t-amyl peroxides and non t-amyl peroxides and/or blends thereof for use in the practice of this invention.

Step one: determine the time and temperature heat treatment profile limitations for the individual 3D printed article. It is preferred that after a selected time-temperature heat treatment there is no substantial damage to the 3D article that could affect performance or aesthetics. Once an appropriate time-temperature heat treatment profile is determined for a 3D printed article, the preferred peroxides are selected using the process of step two.

Step two: preferred t-amyl type peroxides or blends of t-amyl peroxides and/or t-amyl and non-t-amyl polyoligomeric peroxides described herein are selected such the total original wt % of the peroxide(s) in the 3D printed article will be at least 50 wt % decomposed after the time-temperature heat treatment selected by the process of step one. Preferably there will be no more than about 50 wt % undecomposed peroxide(s) remaining after heat treatment based on the total wt % of the original starting peroxide in the 3D article and/or the total combined wt % of a blend of several peroxides that may be of different half-life activities. More preferably, there will be no more than about 25 wt % total undecomposed peroxide(s) remaining after heat treatment. More preferably, there will be no more than about 12.5 wt % total undecomposed peroxide(s) remaining after heat treatment. More preferably, there will be no more than about 6 wt % total undecomposed peroxides(s) remaining after heat treatment. Even more preferably, there will be no more than about 3 wt % total undecomposed peroxides(s) remaining after heat treatment. Even more preferably there will be no more than about 1.5 wt % total undecomposed peroxides(s) remaining after heat treatment.

Following these two steps, the preferred peroxide or peroxides are easily identified for use in the practice of this invention. A preferred peroxide candidate is confirmed using peroxide half-life time at the cure temperature, wherein at least 2 half-lives, preferably 3 half-lives, more preferably at least 4 half-lives, more preferably at least 5 half-lives, even more preferably at least 6 half-lives, or more, of peroxide decomposition occurs using the conditions determined in step one.

The concept of peroxide half-life is described herein and may be calculated or obtained for commercially available peroxides for any cure temperature. To determine the minimum cure time at the cure temperature, the calculated peroxide half-life time in minutes at the cure temperature is multiplied by 2, 3, 4, 5 or 6 to provide a target cure time at that cure temperature. This final time-temperature profile chosen to deliver the desired wt % of peroxide decomposition as per our teachings, should be cross-checked against any heat restrictions found in step one. One skilled in the art can do these calculations for isothermal or variable temperature profiles.

Ideally, if possible, a 3D printed article should be cured so that at least four to six half-lives, or more, of peroxide has decomposed.

| wt % | Number of | wt % |
|---|---|---|
| Decomposed | Peroxide | Undecomposed |
| Peroxide | Half-Lives | Peroxide |
| 0.00% | 0.0 | 100.00% |
| 50.00% | 1.0 | 50.00% |
| 75.00% | 2.0 | 25.00% |
| 87.50% | 3.0 | 12.50% |
| 93.75% | 4.0 | 6.25% |
| 96.88% | 5.0 | 3.13% |
| 98.44% | 6.0 | 1.56% |
| 99.22% | 7.0 | 0.78% |
| 99.61% | 8.0 | 0.39% |
| 99.80% | 9.0 | 0.20% |
| 99.90% | 10.0 | 0.10% |

For example, using these two steps detailed above, if a 3D part can be cured at about 125° C. up to but no higher than about 135° C. for about 30 minutes without substantial damage, then preferred peroxides used in the practice of this invention can be selected from the hemi-peroxyketal (Luperox® V10) whose chemical name is: 1-t-amylperoxy-1-methoxy-3,3,5-trimethyl cyclohexane and/or the diperoxyketal Luperox® 531M80 whose chemical name is 1,1-di(t-amylperoxy)cyclohexane. It may be preferred to use a combination of two peroxides, wherein the lower half-life peroxide, such as 1-t-amylperoxy-1-methoxy-3,3,5-trimethyl cyclohexane is used at a higher peroxide concentration on a wt % basis than the more thermally stable (higher half-life time peroxide) such as 1,1-di(t-amylperoxy)cyclohexane such that the faster decomposing peroxide is used in equal wt % and preferably used at a higher concentration than the more thermally stable peroxide.

Depending on the difference in half-life when using two (or more) peroxides, a blend of 1.5:1 to 10:0.1 wt % ratio on a pure peroxide basis can be considered for the lower half-life: higher half-life ratio. The larger the difference in half-life between the peroxides, the greater the first number in the ratio. The peroxide blend ratio can be chosen using the half-life characteristics of the peroxide in conjunction with the two steps described above, so that when using the profile selected in step one, that the novel peroxide blend as described herein will undergo a minimum of 50 wt % decomposition during the time-temperature profile selected in step one.

More preferred peroxide(s) used in the practice of this invention will depend upon the preferred time and temperature variables chosen from step one as illustrated below.

| | Luperox ® V10 | Luperox ® 531M80 |
|---|---|---|
| Cure ° C. | Half-life time in minutes | Half-life time in minutes |
| 125.0 | 6.21 | 13.75 |
| 130.0 | 3.65 | 8.00 |
| 135.0 | 2.17 | 4.71 |
| 140.0 | 1.31 | 2.81 |
| 145.0 | 0.80 | 1.70 |
| 150.0 | 0.49 | 1.04 |
| 155.0 | 0.31 | 0.64 |
| 160.0 | 0.19 | 0.40 |
| 165.0 | 0.12 | 0.25 |

For example, at 125° C. for 30 minutes the singular use of Luperox® V10 for 30 minutes may be chosen. This peroxide will undergo (30 cure minutes÷6.21 minutes Luperox® V10 peroxide half-life=) 4.8 half-lives of Luperox® V10 0 peroxide decomposition which is within the 4 to 6 half-lives preferred amount of peroxide decomposition.

At 135° C. cure temperature for 30 minutes, a blend of Luperox® V10 and Luperox® 531M80 may be used. At 135° C. and 30 minutes Luperox® V100 undergoes 13.8 half-lives (=30 cure minutes÷2.17 half-life minutes) and Luperox® 531M80 undergoes 6.36 half-lives of decomposition (=30 cure minutes÷4.71 minutes half-life). Thus, in this example it is preferred to use more of Luperox® V10 versus Luperox® 531M80. As Luperox® V100 is decomposing twice as fast as Luperox® 531M80 (13.8 half-lives÷6.36 half-lives≡2), a blend comprising two times more of Luperox® V10 (based on % active oxygen) is combined with Luperox® 531M80. In such a formulation, both peroxides will decompose to a uniform final level and provide a well cured 3D printed part.

Alternatively for a 135° C. for 30 minutes cure profile, a 50:50 wt % blend of Luperox® V10 and Luperox® 531M80 may be used.

For a 160° C. cure temperature at 5 minutes cure time, a blend of Luperox® 531M80 and Luperox® JWEB™ 50 (a blend of a t-amyl and non t-amyl peroxide which is also a polyoligomeric peroxide, respectively) may be preferred based on their half-life performance.

At 160° C. cure temperature and 5 minutes, Luperox® 531M80 will undergo 12.5 half-lives of decomposition or about 99.9% decomposition of the peroxide (=5 cure minutes÷0.4 half-life time) and Luperox® JWEB™50 will undergo 5.26 half-lives of peroxide decomposition (=5 cure minutes÷0.95 half-life minutes) which is about 97% decomposition of the Luperox® JWEB™ 50 original concentration.

| | Luperox ® 531M80 | Luperox ® JWEB ™50 |
|---|---|---|
| Cure ° C. | Half-life time in minutes | Half-life time in minutes |
| 150.0 | 1.04 | 2.43 |
| 155.0 | 0.64 | 1.51 |
| 160.0 | 0.40 | 0.95 |
| 165.0 | 0.25 | 0.60 |

### Measurement of Peroxide Half-Life

Peroxide half-life is determined using dilute solutions of peroxide dissolved in a solvent. By using a radical scavenging solvent, one assures the peroxide undergoes first order kinetics. Solvents such as decane or dodecane have been found suitable for most peroxyesters, diperoxyketals, monoperoxycarbonates, hemi-peroxyketals and dialkyl type peroxides when decomposed in 0.1 to 0.2 Molar concentrations in these solvents. The decomposition of a peroxide under these conditions is a first order, irreversible, unimolecular-type first order reaction.

When a (0.1 to 0.2M) dilute peroxide solution in an appropriate solvent is subjected to a fixed isothermal, time-temperature profile resulting in a first-order peroxide decomposition, the rate of disappearance of the peroxide concentration is given by Equation (1).

$$- \frac{dC}{dt} = kC \qquad ( 1 )$$

where k is the first order rate constant (temperature dependent) in inverse seconds and C is the concentration of the organic peroxide in the solvent.

Rearranging Equation (1) and integrating between the time limits (t=0 to time “t”) and the peroxide concentration limits of C₀ to Cₜ, Equation (2) is obtained wherein C₀ is the starting peroxide concentration and Cₜ is the peroxide concentration after a particular point in time (t) at a fixed temperature T. The peroxide concentrations are determined by well-known methods of chemical analysis employed by peroxide plant QC labs that use either liquid chromatography, titration, gas chromatography methods or a combination thereof.

$$- {\int }_{C 0}^{Ct} \frac{1}{C} dC = k {\int }_{0}^{t} dt \qquad ( 2 )$$

where we use the identity

$$\int \frac{1}{x} dx = ln ( x )$$

to obtain Equation (3)

$$ln [ \frac{C 0}{Ct} ] = kt \qquad ( 3 )$$

Using Equation (3) and the numerical results of the peroxide concentration from chemical analysis of the peroxide decomposition obtained at specified times under a single isothermal condition (i.e., at a specific set temperature T) a linear plot of ln(C0/Ct) in the y axis versus time t (in seconds) will provide a straight line plot, where the slope of the line obtained by linear regression is k in inverse seconds.

Repeating this exercise for several different temperatures, one obtains several first order rate constants “k” in 1/sec for the peroxide being studied at several different temperatures “T” in degrees Kelvin. Ideally, five to six isothermal temperature studies minimum should be run to develop a data set of k and T values to determine the Arrhenius parameters in Equation (5). Once the E and A values are determined, the Arrhenius equation can then be used to find any k value for a desired temperature to determine the peroxide t ½ half-life using Equation 4 at that temperature.

Peroxide half-life (t_{1/2}) is simply the time “t” taken for any peroxide concentration to fall to one-half of its original value at a specific temperature “T”. So to determine the half-life time at an isothermal fixed temperature using Equation (3), it may be simply written that the final concentration at time “t” is one-half of the original peroxide concentration or Cₜ=C₀/2.

Replacing Cₜ with C₀/2 in Equation (3) a relationship between the temperature dependent rate constant “k” and peroxide half-life time “tin” is obtained as provided in Equation (4).

ln[2]=k t_{1/2}; rearranging gives us t_{1/2}=ln(2)/k≡0.693147180559945 . . . /k (4)

where t_{1/2} is the half-life time in seconds for a calculated k value at temperature T. Once the activation energy E and prexponential A values are determined for the Arrhenius equation, a unique k value in 1/sec can be calculated from a temperature in degrees Kelvin.

Using the Arrhenius Equation (5) and taking the natural log (i.e., In) and plotting ln(k) versus (1/T) for at a minimum of five to six temperatures, one obtains a straight line plot where the slope of the line is (−E/R) and the y-intercept will be ln(A). Thus, one has now determined all the required kinetic data (i.e., the E and A values) to calculate a rate constant “k” for any temperature ‘T’.

k=A*e^{-E/RT} (5)

the Arrhenius equation, where:
R is the gas constant 1.987 cal/° Kmole
T is the temperature in ° K
E is the activation energy in calories/mole
A is the pre-exponential in inverse seconds
k is the temperature dependent rate constant in inverse seconds

### Evaluation of Peroxides

There are two common ways that different peroxides can be compared to each other:
(a) Different peroxides can be evaluated on an equal weight basis, “as is” directly from the commercial container.
(b) Another way is to evaluate the different peroxides on an equal active oxygen basis.

Equation (6) below may be used to calculate active oxygen A[O], wherein G is the number of oxygen-oxygen (—OO—) groups in the peroxide molecule, MW is the peroxide molecular weight and % Assay is the chemically determined purity (e.g., 95.4%) of a peroxide typically obtained from the certificate of analysis generated by the peroxide manufacturing plant. The concept of active oxygen content is useful for comparing different peroxides while trying to make sure the concentrations of the peroxy groups (—OO—) are equivalent.

$$\begin{matrix}A [ O ] = \{ \frac{[ 16 * G ]}{[ MW ]} \} * \% Assay & ( 6 ) \\ {P}_{1} * {A [ O ]}_{1} = {P}_{2} * {A [ O ]}_{2} & ( 7 )\end{matrix}$$

Using Equation (7), two or more peroxides can be compared to each other. For example, it may be desired to compare the use level of peroxide #1 (a control) to a different peroxide #2 on an equal active oxygen basis. The current use amount (weight) of peroxide #1 in the system is P₁ and it is multiplied by the active oxygen of that peroxide which is A[O]₁. One can easily solve for the weight of the new peroxide #2, (P₂) using Equation (7), as its active oxygen A[O]₂ is easily determined using Equation (6) from the % assay provided by the certificate of analysis.

### Photo-Releasable Bases

In certain embodiments, a composition in accordance with the present invention comprises at least one photo-releasable base, in particular at least one photo-releasable amine.

Such compounds are known in the art and are sometimes also referred to as “photoactivatable nitrogen bases,” “photogenerated amines,” “photolatent amines” or “photolatent amine bases.” The term “photo-releasable amine,” as used herein, also includes photo-releasable amidines. A photo-releasable amine is a compound that contains at least one blocked or masked amine group which at room temperature (25° C.) in the absence of ultraviolet radiation is stable in the presence of the peroxide(s) which are present in the same composition as the photo-releasable amine. That is, under such conditions, reduction of the peroxide(s) by the photo-releasable amine does not occur to any significant extent. However, when the composition is exposed to radiation such as ultraviolet radiation, the photo-releasable amine undergoes a reaction which results in removal or conversion of a masking or blocking group and the generation of at least one free amino group. The free amino group which is released may be a primary, secondary or tertiary amino group, but in preferred embodiments is a tertiary amino group. The amino group may be part of an amidine moiety. The compound or compounds containing one or more free amino groups or other basic groups which are thereby released are capable of functioning as activators or promoters in redox reactions involving the peroxide(s) present in the composition, whereby initiation of a desired curing or polymerization of the photocurable (e.g., ethylenically unsaturated) compound(s) additionally present in the composition takes place. The addition of such a photo-releasable base allows the curing/polymerization reaction to be initiated at a lower temperature as compared to an analogous composition which does not contain such a photo-releasable base.

Examples of suitable photo-releasable amines include, but are not limited to, compounds of general formula Z-A wherein Z is a photolabile group and A is an amine precursor group, which typically is covalently bonded to Z.

Photo-releasable amines suitable for use in the present invention are described, for example, in the following publications, each of which is incorporated herein by reference in its entirety for all purposes: US Patent Application Publication No. US 2011/0190412; WO 98/32756; WO 98/41524; WO 03/33500; EP 898202; WO 05/007637; WO 97/31033; Shirai et al., Prog. Polym. Sci., Vol. 21, pages 1-45 (1996); Crivello et al., “Photoinitiators for Free Radical Cationic & Anionic Photopolymerization,” 2^{nd} Edition, Volume III in the series “Chemistry & Technology of UV & EB Formulation for Coatings, Inks & Paints,” John Wiley/SITA Technology Limited, London, 1998, Chapter IV, pages 479-544; U.S. Pat. No. 6,124,371; Dietliker et al., “Novel chemistry for UV coatings,” European Coatings Journal, October 2005, page 20; Dietliker et al., “Photolatent Amines: New Opportunities in Radiation Curing, e/5 2004 (RadTech USA), Technical Conference Proceedings, May 2-5, 2004; Bull, “Photogenerated Amines as Novel Crosslinking Agents,” e/5 2004 (RadTech USA), Technical Conference Proceedings, May 2-5, 2004; Dietliker et al., “Photolatent Tertiary Amines—A New Technology Platform for Radiation Curing,” CHIMIA International Journal for Chemistry, Vol. 61, No. 10, October 2007, pages 655-660(6); US Patent Application Publication No. US 2004/0242867; and US Patent Application Publication No. US 2010/0105794.

Typically, if a photo-releasable base or combination of photo-releasable bases is present in the photocurable compositions of the present invention, it is present in a total amount of from about 0.005 to about 5% by weight based on the total weight of the photocurable compound also present.

Preferably, the amount of photo-releasable base used in the photocurable composition is selected such that the concentration of the final generated basic species (e.g., tertiary amine) is at most one-tenth of the concentration of the peroxide present in the photocurable composition. If too much base (e.g., amine) is present, over promotion can occur, leading to excessive ionic decomposition of the peroxide versus the desired generation of free-radicals.

### Unsaturated Peroxides

According to one aspect, a composition in accordance with the invention includes at least one ethylenically unsaturated organic peroxide (that is, an organic peroxide containing at least one carbon-carbon double bond). The phrase “ethylenically unsaturated organic peroxide” as used herein is intended to encompass organic peroxides that contain one or more carbon-carbon double bond functional groups per molecule that are capable of participating in free radical reactions, such as with other ethylenically unsaturated compounds (e.g., (meth)acrylates). The ethylenically unsaturated organic peroxide(s) contain at least two adjacent carbon atoms linked by two bonds (e.g., an unsaturated group). In other words, the ethylenically unsaturated organic peroxide(s) may be classified as peroxide-containing mono-olefins or alkenes (i.e., having an organo group which is a straight- or branched-chain hydrocarbon with one double bond), cyclo-olefins or cycloalkenes (i.e., having an organo group which is a cyclic hydrocarbon ring with one double bond), or diolefins or dienes (i.e., having two organo groups each of which contains a carbon-carbon double bond or a single organo group containing two carbon-carbon double bonds), etc.

Any suitable ethylenically unsaturated organic peroxide or combination of ethylenically unsaturated organic peroxides may be selected by one skilled in the art, based on the description of the invention provided herein. For example, the at least one carbon-carbon double bond may be furnished by at least one isopropenyl group attached to an aromatic ring or a tert-butylperoxy or tert-amylperoxy group. The at least one tert-butylperoxy or tert-amylperoxy group may be bonded to a tertiary carbon atom. In one embodiment, the tertiary carbon atom may be bonded to two alkyl (e.g., methyl) groups and an aryl (e.g., phenyl or substituted phenyl) group.

The at least one ethylenically unsaturated organic peroxide may be a monomeric dialkyl ethylenically unsaturated organic peroxide. The term “monomeric” peroxide refers to an organic peroxide containing at least one ethylenically unsaturated group capable of reacting with compounds bearing free radicals and other ethylenically unsaturated compounds such as (meth)acrylate-functionalized monomers and oligomers to form polymeric networks (which may be crosslinked). The monomeric portion of the organic peroxide may become incorporated into the polymeric network, while also contributing to increased crosslinking of the polymer.

An unsaturated peroxide is a peroxide compound that has at least one carbon-carbon double bond that is able to participate in a free radical reaction, e.g., capable of being polymerized by a photo (e.g., UV)-initiator. Use of unsaturated peroxides prevents migration of peroxide from the interior to the surface of the article being formed from the photocurable composition, and/or prevents peroxide volatility if there is a long delay between photo (e.g., UV) curing and the heat treatment step. Conventional (saturated) peroxides are somewhat volatile and are able to evaporate out of an article (e.g., a 3D part) over time if the article is not heat treated soon after being initially formed (e.g., after 3D printing). Thus, the use of an unsaturated peroxide helps to ensure that at least some of the peroxide remains present for the heat treating and final curing step. Furthermore, there is less chance for porosity or bubble formation within an article (e.g., a 3D printed polymer part). Its use also reduces the amount of low molecular weight peroxide decomposition by-products. Lastly, decomposition of the polymeric peroxide results in increased chain branching, polymer molecular weight increase and crosslinking, sll og which lead to improved physical properties in the cured composition.

As used herein, “dialkyl type peroxides,” “dialkyl peroxide class,” or “dialkyl peroxides” may be used interchangeably to define a peroxide comprising a dialkyl structure, which are well known to those of ordinary skill in the art. In particular, an organic peroxide possesses one or more oxygen-oxygen bonds and at least one organo group, as illustrated by the generic structural formula R—OO—R′ wherein both R and R′ are organic groups. In a dialkyl peroxide, R and R′ are both alkyl groups (i.e., CₙCHₙ₊₁), such as methyl, ethyl, propyl, butyl, pentyl, etc. or substituted alkyl groups (wherein the alkyl group may be substituted with other types of groups, including aryl groups). In other words, two alkyl or substituted alkyl groups are adjacent to the oxygen-oxygen peroxy moiety. In preferred embodiments, each carbon atom bonded to an oxygen of an oxygen-oxygen peroxy moiety in the dialkyl organic peroxide is a tertiary carbon atom.

The dialkyl peroxides may also contain other groups in addition to the alkyl groups discussed above, such as aryl groups, additional alkyl groups, aryl alkyl groups, endo groups, acrylate groups, allylic groups, diallylic groups, triallylic groups, di(meth)acrylate groups, (meth)acrylate groups, fumarate groups, maleate groups, itaconate groups, and the like.

In one embodiment, the dialkyl peroxide may be an aryl-containing dialkyl peroxide (i.e., at least one aryl group, such as a phenyl, benzyl, or tolyl group, derived from an aromatic ring, is present in the organic group R and/or R′).

Suitable ethylenically unsaturated organic peroxides include compounds containing at least one peroxy group (—O—O—) and at least one organo group containing at least one carbon-carbon double bond. The organo group may, for example, be a hydrocarbyl group such as an allyl or isopropenyl group (which may, in one embodiment, be a substituent on an aromatic group, such as a benzene ring). The organo group may also be, for example, an alpha,beta-unsaturated ester group such as an acrylate, methacrylate, fumarate, itaconate or maleate group.

Any suitable ethylenically unsaturated organic peroxide may be selected. Suitable ethylenically unsaturated organic peroxides may include, for example, 1-(2-tert-butylperoxyisopropyl)-3-isopropenylbenzene [also known as tert-butyl-3-isopropenylcumyl peroxide or m-isopropenylcumyl tert-butyl peroxide]; 1-(2-tert-butylperoxyisopropyl)-4-isopropenylbenzene; 1-(2-tert-butylperoxyisopropyl)-3,4-diisopropenylbenzene; 1,3-di(tert-butylperoxy)diisopropylbenzene-5-isopropenyl; 1,4-di(tert-butylperoxy)diisopropylbenzene-2-isopropenyl; 1-(2-tert-amylperoxyisopropyl)-3-isopropenylbenzene; 1-(2-tert-amylperoxyisopropyl)-4-isopropenylbenzene; 1-(2-tert-amylperoxyisopropyl)-3,4-diisopropenylbenzene; 1,3-dimethyl-3(t-butylperoxy)butyl N[1 (3(1-methylethenyl)phenyl) 1-methylethyl]carbamate; 2,4-diallyloxy-6-tert-butylperoxide-1,3,5-triazine; 1,3-dimethyl-3(t-butylperoxy) butyl methacrylate; 1,3-dimethyl-3(t-butylperoxy) butyl acrylate; 3-methyl-3(t-butylperoxy) butyl methacrylate; 3-methyl-3(t-butylperoxy)butyl acrylate; di-[1,3-dimethyl-3-(t-amylperoxy)butyl]fumarate; di-[1,3-dimethyl-3-(t-butylperoxy)butyl]fumarate; ethyl-1,3-dimethyl-3-(t-butylperoxy)butyl fumarate; 1,3-dimethyl-3-(t-butylperoxy)butyl itaconate; 1,3-dimethyl-3-(t-butylperoxy)butyl maleate; ethyl-1,3-dimethyl-3-(t-butylperoxy)butyl itaconate; di[1,3-dimethyl-3-(t-butylperoxy)butyl]itaconate; and mixtures thereof.

In one embodiment of the invention, at least one organic peroxide is used which is both an ethylenically unsaturated peroxide and a t-amyl peroxide. Examples of such peroxides include 1-(2-tert-amylperoxyisopropyl)-3-isopropenylbenzene; 1-(2-tert-amylperoxyisopropyl)-4-isopropenylbenzene; 1-(2-tert-amylperoxyisopropyl)-3,4-diisopropenylbenzene; and di-[1,3Dimethyl-3-(t-amylperoxy)butyl]fumarate.

The structure below represents ethylenically unsaturated peroxides such as 1,3-dimethyl-3(t-butylperoxy)butyl methacrylate; 1,3-dimethyl-3(t-butylperoxy)butyl acrylate and other alkylacrylates where the substituent attached to the alpha carbon of the C═C moiety could be H, CH₃, or a longer chain alkyl group. Also suitable for use in the present invention are analogous compounds wherein the t-butyl group is replaced by a t-amyl group.

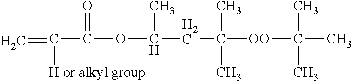

The structure below is an ethylenically unsaturated organic peroxide whose chemical name is 1,3Dimethyl-3-(t-butylperoxy)butyl itaconate. Analogous peroxides wherein the t-butyl group is replaced by a t-amyl group are also suitable for use.

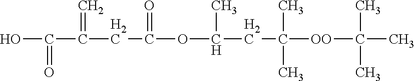

Di[1,3-dimethyl-3-(t-butylperoxy)butyl]itaconate, the structure of which is shown below, is another suitable ethylenically unsaturated organic peroxide. One or both of the t-butyl groups may be replaced by a t-amyl group.

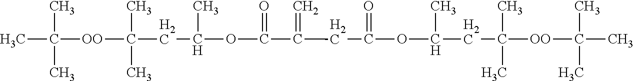

In an exemplary embodiment, the ethylenically unsaturated organic peroxide is 1-(2-tert-butylperoxyisopropyl)-3-isopropenylbenzene (IP-D16). The chemical structure of IP-D16 is shown below, wherein the isopropenyl portion (which may be considered a monomeric portion) is attached to a benzene ring. IP-D16 is considered to be an ethylenically unsaturated organic peroxide which is both a dialkyl organic peroxide and a monomeric organic peroxide. The t-amyl analogue of IP-D16, wherein a t-amyl group replaces the t-butyl group, is also suitable for use.

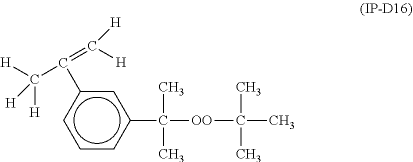

### Other Peroxides

In addition to one or more of the above-described t-amyl peroxides and unsaturated organic peroxides, photocurable compositions in accordance with the present invention may comprise one or more other types of peroxides, in particular one or more other types of organic peroxides. However, in other embodiments, the photocurable composition does not comprise any type of peroxide other than t-amyl peroxide and, optionally, ethylenically unsaturated peroxide.

If present, such additional peroxides may be any of the various types of peroxides known in the art or combinations thereof. For example, the additional peroxide(s) may be one or more t-butyl peroxides, including for example t-butyl peroxides selected from the group consisting of hemi-peroxyketals, diperoxyketals, peroxyesters, dialkyl peroxides, hydroperoxides, monoperoxycarbonates and combinations thereof (each of which is characterized by the presence of at least one t-butyl group). There may be certain advantages, due to half-life characteristics and processing conditions, to using combinations of one or more t-amyl peroxides and one or more t-butyl peroxides. For example, the weight ratio of t-amyl peroxide to t-butyl peroxide may be 100:1 to 90:10, or from 70:30 to 60:40 or greater than 50:30, in various embodiments of the invention.

### Photoinitiators

The compositions of the present invention include at least one photoinitiator and, when formulated to contain one or more photocurable compounds, are curable with radiant energy. Any of the photoinitiators known in the art may be employed. For example, the photoinitiator(s) may be selected from the group consisting of α-hydroxyketones, phenylglyoxylates, benzyldimethylketals, α-aminoketones, mono-acyl phosphines, bis-acyl phosphines, phosphine oxides, metallocenes and combinations thereof.

Suitable α-hydroxyketone photoinitiators include, but are not limited to, 1-hydroxy-cyclohexyl-phenyl-ketone and/or 2-hydroxy-2-methyl-1-phenyl-1-propanone. In other embodiments, the at least one photoinitiator is or includes a phosphine oxide, in particular bis(2,4-6-trimethylbenzoyl)phenyl phosphine oxide. Other exemplary and suitable photoinitiators include 2-methylanthraquinone, 2-ethylanthraquinone, 2-chloroanthraquinone, 2-benzyanthraquinone, 2-t-butylanthraquinone, 1,2-benzo-9,10-anthraquinone, benzyl, benzoin, benzoin methyl ether, benzoin ethyl ether, benzoin isopropyl ether, alpha-methylbenzoin, alpha-phenylbenzoin, Michler's ketone, benzophenone, 4,4′-bis-(diethylamino) benzophenone, acetophenone, 2,2-diethyloxyacetophenone, diethyloxyacetophenone, 2-isopropylthioxanthone, thioxanthone, diethyl thioxanthone, 1,5-acetonaphthylene, ethyl-p-dimethylaminobenzoate, benzil ketone, α-hydroxy keto, 2,4,6-trimethylbenzoyldiphenyl phosphine oxide, benzyl dimethyl ketal, benzil ketal (2,2-dimethoxy-1,2-diphenylethanone), 1-hydroxycylclohexyl phenyl ketone, 2-methyl-1-[4-(methylthio) phenyl]-2-morpholinopropanone-1,2-hydroxy-2-methyl-1-phenyl-propanone, oligomeric α-hydroxy ketone, phenylbis(2,4,6-trimethylbenzoyl)phosphine oxide, ethyl-4-dimethylamino benzoate, ethyl(2,4,6-trimethylbenzoyl)phenyl phosphinate, anisoin, anthraquinone, anthraquinone-2-sulfonic acid, sodium salt monohydrate, (benzene) tricarbonylchromium, benzil, benzoin isobutyl ether, benzophenone/1-hydroxycyclohexyl phenyl ketone, 50/50 blend, 3,3′,4,4′-benzophenonetetracarboxylic dianhydride, 4-benzoylbiphenyl, 2-benzyl-2-(dimethylamino)-4′-morpholinobutyrophenone, 4,4′-bis(diethylamino)benzophenone, 4,4′-bis(dimethylamino)benzophenone, camphorquinone, 2-chlorothioxanthen-9-one, dibenzosuberenone, 4,4′-dihydroxybenzophenone, 2,2-dimethoxy-2-phenylacetophenone, 4-(dimethylamino)benzophenone, 4,4′-dimethylbenzil, 2,5-dimethylbenzophenone, 3,4-dimethylbenzophenone, diphenyl(2,4,6-trimethylbenzoyl)phosphine oxide/2-hydroxy-2-methylpropiophenone, 50/50 blend, 4′-ethoxyacetophenone, 2,4,6-trimethylbenzoyldiphenylphophine oxide, phenyl bis(2,4,6-trimethyl benzoyl)phosphine oxide, ferrocene, 3′-hydroxyacetophenone, 4′-hydroxyacetophenone, 3-hydroxybenzophenone, 4-hydroxybenzophenone, 1-hydroxycyclohexyl phenyl ketone, 2-hydroxy-2-methylpropiophenone, 2-methylbenzophenone, 3-methylbenzophenone, methybenzoylformate, 2-methyl-4′-(methylthio)-2-morpholinopropiophenone, phenanthrenequinone, 4′-phenoxyacetophenone, (cumene)cyclopentadienyl iron (ii) hexafluorophosphate, 9,10-diethoxy and 9,10-dibutoxyanthracene, 2-ethyl-9,10-dimethoxyanthracene, thioxanthen-9-one and combinations thereof.

The amount of photoinitiator is not considered to be critical, but may be varied as may be appropriate depending upon the photoinitiator(s) selected, the amount of photocurable compound(s) present in the photocurable composition, the radiation source, the radiation wavelength(s) and the radiation conditions used, among other factors. Typically, however, the amount of photoinitiator may be from 0.05% to 10% by weight, based on the total weight of the photocurable composition (not including any water or non-reactive solvent that may be present).

### Photocurable Compounds

Curable compositions in accordance with the present invention are formulated to comprise at least one photocurable compound, i.e., a compound capable of reacting and participating in a curing reaction (generally involving polymerization and/or crosslinking) when the photocurable composition is exposed to radiation (e.g., ultraviolet radiation). Photocurable compounds suitable for use include both monomeric and oligomeric photocurable compounds. Ethylenically unsaturated compounds are especially preferred for use as the photocurable compounds in the present invention. Suitable ethylenically unsaturated compounds suitable for use include compounds containing at least one carbon-carbon double bond, in particular a carbon-carbon double bond capable of participating in a free radical reaction wherein at least one carbon of the carbon-carbon double bond becomes covalently bonded to an atom, in particular a carbon atom, in a second molecule. Such reactions may result in a polymerization or curing whereby the ethylenically unsaturated compound becomes part of a polymerized matrix or polymeric chain. In various embodiments of the invention, the ethylenically unsaturated compound(s) may contain one, two, three, four, five or more carbon-carbon double bonds per molecule. Combinations of multiple ethylenically unsaturated compounds containing different numbers of carbon-carbon double bonds may be utilized in the compositions of the present invention. The carbon-carbon double bond may be present as part of an α,β-unsaturated carbonyl moiety, e.g., an α,β-unsaturated ester moiety such as an acrylate functional group or a methacrylate functional group. A carbon-carbon double bond may also be present in the additional ethylenically unsaturated compound in the form of a vinyl group —CH═CH₂ (such as an allyl group, —CH₂—CH═CH₂). Two or more different types of functional groups containing carbon-carbon double bonds may be present in the ethylenically unsaturated compound. For example, the ethylenically unsaturated compound may contain two or more functional groups selected from the group consisting of vinyl groups (including allyl groups), acrylate groups, methacrylate groups and combinations thereof.

The compositions of the present invention may, in various embodiments, contain one or more (meth)acrylate functional compounds capable of undergoing free radical polymerization (curing) initiated by exposure to radiation (in particular, ultraviolet radiation). As used herein, the term “(meth)acrylate” refers to methacrylate (—O—C(═O)—C(CH₃)═CH₂) as well as acrylate (—O—C(═O)—CH═CH₂) functional groups. Suitable free radical-curable (meth)acrylates include compounds containing one, two, three, four or more (meth)acrylate functional groups per molecule; the free radical-curable (meth)acrylates may be oligomers or monomers. The at least one additional ethylenically unsaturated monomer or oligomer may include, for example, at least one compound selected from the group consisting of cyclic, linear and branched mono-, di- and tri-(meth)acrylate-functionalized monomers and oligomers.

Suitable free radical-curable (meth)acrylate oligomers include, for example, polyester (meth)acrylates, epoxy (meth)acrylates, polyether (meth)acrylates, polyurethane (meth)acrylates, acrylic (meth)acrylate oligomers, epoxy-functional (meth)acrylate oligomers and combinations thereof. Such oligomers may be selected and used in combination in order to enhance the flexibility, strength and/or modulus, among other attributes, of a cured photocurable composition.

Exemplary polyester (meth)acrylates include the reaction products of acrylic or methacrylic acid or mixtures thereof with hydroxyl group-terminated polyester polyols. The reaction process may be conducted such that a significant concentration of residual hydroxyl groups remains in the polyester (meth)acrylate or may be conducted such that all or essentially all of the hydroxyl groups of the polyester polyol have been (meth)acrylated. The polyester polyols can be made by polycondensation reactions of polyhydroxyl functional components (in particular, diols) and polycarboxylic acid functional compounds (in particular, dicarboxylic acids and anhydrides). The polyhydroxyl functional and polycarboxylic acid functional components can each have linear, branched, cycloaliphatic or aromatic structures and can be used individually or as mixtures.

Examples of suitable epoxy (meth)acrylates include the reaction products of acrylic or methacrylic acid or mixtures thereof with glycidyl ethers or esters.

Suitable polyether (meth)acrylates include, but are not limited to, the condensation reaction products of acrylic or methacrylic acid or mixtures thereof with polyetherols which are polyether polyols. Suitable polyetherols can be linear or branched substances containing ether bonds and terminal hydroxyl groups. Polyetherols can be prepared by ring opening polymerization of cyclic ethers such as tetrahydrofuran or alkylene oxides with a starter molecule. Suitable starter molecules include water, hydroxyl functional materials, polyester polyols and amines.

Polyurethane (meth)acrylates (sometimes also referred to as “urethane (meth)acrylates”) capable of being used in the compositions of the present invention include urethanes based on aliphatic and/or aromatic polyester polyols and polyether polyols and aliphatic and/or aromatic polyester diisocyanates and polyether diisocyanates capped with (meth)acrylate end-groups. Suitable polyurethane (meth)acrylates include, for example, aliphatic polyester-based urethane diacrylate oligomers, aliphatic polyether-based urethane diacrylate oligomers, as well as aliphatic polyester/polyether-based urethane diacrylate oligomers.

In various embodiments, the polyurethane (meth)acrylates may be prepared by reacting aliphatic and/or aromatic diisocyanates with OH group terminated polyester polyols (including aromatic, aliphatic and mixed aliphatic/aromatic polyester polyols), polyether polyols, polycarbonate polyols, polycaprolactone polyols, polydimethysiloxane polyols, or polybutadiene polyols, or combinations thereof to form isocyanate-functionalized oligomers which are then reacted with hydroxyl-functionalized (meth)acrylates such as hydroxyethyl acrylate or hydroxyethyl methacrylate to provide terminal (meth)acrylate groups. For example, the polyurethane (meth)acrylates may contain two, three, four or more (meth)acrylate functional groups per molecule.

One or more urethane diacrylates may be employed in certain embodiments of the invention. For example, the photocurable composition may comprise at least one urethane diacrylate such as a difunctional aromatic urethane acrylate oligomer, a difunctional aliphatic urethane acrylate oligomer or combinations thereof. In certain embodiments, a difunctional aromatic urethane acrylate oligomer, such as that available from Sartomer USA, LLC (Exton, Pa.) under the trade name CN9782, may be used as the at least one urethane diacrylate. In other embodiments, a difunctional aliphatic urethane acrylate oligomer, such as that available from Sartomer USA, LLC under the trade name CN9023, may be used as the at least one urethane diacrylate. CN9782, CN9023, CN978, CN965, CN9031, CN8881, and CN8886, all available from Sartomer USA, LLC, may all be advantageously employed as urethane diacrylates in the compositions of the present invention.

Suitable acrylic (meth)acrylate oligomers (sometimes also referred to in the art as “acrylic oligomers”) include oligomers which may be described as substances having an oligomeric acrylic backbone which is functionalized with one or (meth)acrylate groups (which may be at a terminus of the oligomer or pendant to the acrylic backbone). The acrylic backbone may be a homopolymer, random copolymer or block copolymer comprised of repeating units of acrylic monomers. The acrylic monomers may be any monomeric (meth)acrylate such as C1-C6 alkyl (meth)acrylates as well as functionalized (meth)acrylates such as (meth)acrylates bearing hydroxyl, carboxylic acid and/or epoxy groups. Acrylic (meth)acrylate oligomers may be prepared using any procedures known in the art such as oligomerizing monomers, at least a portion of which are functionalized with hydroxyl, carboxylic acid and/or epoxy groups (e.g., hydroxyalkyl(meth)acrylates, (meth)acrylic acid, glycidyl (meth)acrylate) to obtain a functionalized oligomer intermediate, which is then reacted with one or more (meth)acrylate-containing reactants to introduce the desired (meth)acrylate functional groups. Suitable acrylic (meth)acrylate oligomers are commercially available from Sartomer USA, LLC under products designated as CN820, CN821, CN822 and CN823, for example.

Free radical-curable monomers suitable for use in the present invention include the following types of monomers (wherein “functional” refers to the number of (meth)acrylate functional groups per molecule, e.g., monofunctional=one (meth)acrylate group per molecule, difunctional=two (meth)acrylate groups per molecule):
i) cyclic monofunctional (meth)acrylate monomers, such as isobornyl (meth)acrylate, cyclohexyl (meth)acrylate, 4-tert-butyl cyclohexyl (meth)acrylate and alkoxylated analogues thereof;
ii) linear and branched monofunctional (meth)acrylate monomers, such as isodecyl (meth)acrylate, ethoxyethoxyethyl (meth)acrylate, polyethylene mono (meth)acrylates, neopentyl glycol (meth)acrylates and alkoxylated analogues thereof;
iii) cyclic difunctional (meth)acrylate monomers, such as tricyclodecane dimethanol di(meth)acrylate, cyclohexane dimethanol di(meth)acrylate and alkoxylated analogues thereof;
iv) linear difunctional (meth)acrylate monomers, such as polyethylene di(meth)acrylates, neopentyl glycol di(meth)acrylates and alkoxylated analogues thereof; and
v) trifunctional (meth)acrylate monomers, such as triallyl isocyanurate tri(meth)acrylates, trimethylol tri(meth)acrylates and alkoxylated analogues thereof.

Such monomers may be used to reduce the viscosity of the photocurable compositions of the present invention and adjust the flexibility, strength and/or modulus, among other properties, of finished articles obtained by curing the photocurable compositions.

Illustrative examples of suitable free radical-curable monomers include 1,3-butylene glycol di(meth)acrylate, butanediol di(meth)acrylate, 1,6-hexanediol di(meth)acrylate, alkoxylated hexanediol di(meth)acrylate, alkoxylated aliphatic di(meth)acrylate, alkoxylated neopentyl glycol di(meth)acrylate, dodecyl di(meth)acrylate cyclohexane dimethanol di(meth)acrylate, diethylene glycol di(meth)acrylate, dipropylene glycol di(meth)acrylate, n-alkane di(meth)acrylate, polyether di(meth)acrylates, ethoxylated bisphenol A di(meth)acrylate, ethylene glycol di(meth)acrylate, neopentyl glycol di(meth)acrylate, polyester di(meth)acrylate, polyethylene glycol di(meth)acrylate, polypropylene glycol di(meth)acrylate, propoxylated neopentyl glycol diacrylate, tricyclodecane dimethanol diacrylate, triethylene glycol di(meth)acrylate, tetraethylene glycol di(meth)acrylate tripropylene glycol di(meth)acrylate, ditrimethylolpropane tetra(meth)acrylate, dipentaerythritol penta(meth)acrylate, ethoxylated pentaerythritol tetra(meth)acrylate, dipentaerythritol penta(meth)acrylate, dipentaerythritol penta(meth)acrylate, penta(meth)acrylate ester, pentaerythritol tetra(meth)acrylate, ethoxylated trimethylolpropane tri(meth)acrylate, alkoxylated trimethylolpropane tri(meth)acrylate, highly propoxylated glyceryl tri(meth)acrylate, trimethylolpropane tri(meth)acrylate, trimethylolpropane tri(meth)acrylate, pentaerythritol tri(meth)acrylate, propoxylated glyceryl tri(meth)acrylate, propoxylated trimethylolpropane tri(meth)acrylate, trimethylolpropane trimethacrylate, tris (2-hydroxy ethyl) isocyanurate tri(meth)acrylate, 2(2-ethoxyethoxy) ethyl (meth)acrylate, 2-phenoxyethyl (meth)acrylate, 3,3,5-trimethylcyclohexyl (meth)acrylate, alkoxylated lauryl (meth)acrylate, alkoxylated phenol (meth)acrylate, alkoxylated tetrahydrofurfuryl (meth)acrylate, caprolactone (meth)acrylate, cyclic trimethylolpropane formal (meth)acrylate, cycloaliphatic acrylate monomer, dicyclopentadienyl (meth)acrylate, diethylene glycol methyl ether (meth)acrylate, ethoxylated (4) nonyl phenol (meth)acrylate, ethoxylated nonyl phenol (meth)acrylate, isobornyl (meth)acrylate, isodecyl (meth)acrylate, isooctyl (meth)acrylate, lauryl (meth)acrylate, methoxy polyethylene glycol (meth)acrylate, octyldecyl (meth)acrylate, stearyl (meth)acrylate, tetrahydrofurfuryl (meth) acrylate, tridecyl (meth)acrylate, and/or triethylene glycol ethyl ether (meth)acrylate, t-butyl cyclohexyl (meth)acrylate, alkyl (meth)acrylate, dicyclopentadiene di(meth)acrylate, alkoxylated nonylphenol (meth)acrylate, phenoxyethanol (meth)acrylate, octyl (meth)acrylate, decyl (meth)acrylate, dodecyl (meth)acrylate, tetradecyl (meth)acrylate, tridecyl (meth)acrylate, cetyl (meth)acrylate, hexadecyl (meth)acrylate, behenyl (meth)acrylate, diethylene glycol ethyl ether (meth)acrylate, diethylene glycol butyl ether (meth)acrylate, triethylene glycol methyl ether (meth)acrylate, dodecanediol di (meth)acrylate, dodecane di (meth)acrylate, dipentaerythritol penta/hexa(meth)acrylate, pentaerythritol tetra(meth)acrylate, ethoxylated pentaerythritol tetra(meth)acrylate, ethoxylated trimethylolpropane tri(meth)acrylate, trimethylolpropane tri(meth)acrylate, di-trimethylolpropane tetra(meth)acrylate, propoxylated glyceryl tri(meth)acrylate, pentaerythritol tri(meth)acrylate, propoxylated glyceryl tri(meth)acrylate, propoxylated trimethylolpropane tri(meth)acrylate, trimethylolpropane tri(meth)acrylate, and tris (2-hydroxy ethyl) isocyanurate tri(meth)acrylate, and combinations thereof.

Particularly advantageous types of free radical-curable compounds which may be used in combination include, but are not limited to, urethane (meth)acrylates, polyester (meth)acrylates, acrylic (meth)acrylate oligomers, epoxy-functional oligomers, cyclic monofunctional monomers, linear and branched monofunctional monomers, cyclic difunctional monomers, trifunctional monomers and combinations thereof.

### Other Additives

In certain embodiments of the invention, the photocurable composition may contain one or more solvents, in particular one or more organic solvents, which may be non-reactive organic solvents. In various embodiments, the solvent(s) may be relatively volatile, e.g., solvents having a boiling point at atmospheric pressure of not more than 150° C. In other embodiments, the solvent(s) may have a boiling point at atmospheric pressure of at least 40° C.

The solvent(s) may be selected so as to be capable of solubilizing one or more components of the composition and/or adjusting the viscosity or other rheological properties of the composition.

However, the photocurable compositions of the present invention may alternatively be formulated so as to contain little or no non-reactive solvent, e.g., less than 10% or less than 5% or even 0% non-reactive solvent, based on the total weight of the composition. Such solvent-less or low-solvent compositions may be formulated using various components, including for example low viscosity reactive diluents and/or water, which are selected so as to render the composition sufficiently low in viscosity, even without solvent being present, that the composition can be easily applied at a suitable application temperature to a substrate surface so as to form a relatively thin, uniform layer.

According to certain aspects of the invention, the components of the photocurable compositions, and relative amounts of such components, are selected to render the photocurable compositions described herein sufficiently flowable for application to a substrate. For example, in various embodiments of the invention, the photocurable compositions described herein have a viscosity of less than 4000 cPs, or less than 3500 cPs, or less than 3000 cPs or less than 2500 cPs, as measured at 25° C. using a Brookfield viscometer, model DV-II, using a 27 spindle (with the spindle speed varying typically between 50 and 200 rpm, depending on viscosity).

Photocurable compositions in accordance with the present invention may be formulated to comprise one or more accelerators. Such accelerators assist in facilitating the desired decomposition and activation of the t-amyl peroxide or any other type of peroxide which may be present, particularly when the photocurable composition is heated to a temperature above room temperature (25° C.). Accordingly, the accelerator(s) may lower the temperature at which the peroxide(s) begin to undergo significant decomposition to generate free radicals, and/or lower the half-life of the peroxide(s) at the desired post-photocuring heating temperature and/or accelerate the rate at which the peroxide(s) decompose at a given temperature. The at least one accelerator may comprise, for example, at least one amine (e.g., a tertiary amine) and/or one or more other reducing agents based on metal salts (such as, for example, carboxylate salts of transition metals such as iron, cobalt, manganese, vanadium and the like and combinations thereof). As previously described in detail, the accelerator may be supplied in the form of a photo-releasable base.

The compositions of the present invention may optionally contain one or more additives instead of or in addition to the above-mentioned ingredients. Such additives include, but are not limited to, antioxidants (to help improve the long-term heat aging characteristics of the cured composition), ultraviolet absorbers, photostabilizers, foam inhibitors, flow or leveling agents, colorants, pigments, dispersants (wetting agents), slip additives, fillers, thixotropic agents, matting agents, thermoplastics such as acrylic resins that do not contain any free radical-polymerizable functional groups, waxes or other various additives, including any of the additives conventionally utilized in the coating, sealant, adhesive, molding, 3D printing or ink arts.

In one embodiment, the components of the photocurable composition are selected so as to provide a finished article which, after curing of the photocurable composition, is clear (transparent). In another embodiment, one or more fillers, in particular particulate fillers such as pigments and the like, are utilized in the photocurable composition so as to provide an opaque finished (cured) article. Titanium oxide as well as other metal oxides, hydroxides, carbonates and the like may be used as such a filler, for example.

### Initiator Use Levels

In the photocurable compositions of the present invention, the total amount of photoinitiator may range, for example, from 0.1% to 10%, preferably 0.25% to 7%, more preferably from 0.5% to 5% by weight, based on the total weight of photocurable compound (which may be a blend of different photocurable monomers and/or oligomers). Blends of different types of initiators can be used to cover a desired range of active wavelength. For example, blends of Irgacure® 819 (bis(2,4,6-trimethylbenzoyl)-phenylphosphine oxide) and Irgacure® 184 (1-hydroxy-cyclohexyl-phenyl-ketone) may be used. In another example, the Irgacure® 819 can also be used together with Lambson Speedcure® BEM, which is a blend of benzophenone+2-methyl benzophenone+4-methyl benzophenone photoinitiators.

The use level of organic peroxide initiators in the photocurable compositions of the present invention may typically range from 0.01% to 20%; preferably 0.1% to 10%; more preferably 0.1% to 5%; even more preferably 0.1% to 3% by weight based on the total weight of photocurable compound (which may be a blend of different photocurable monomers and/or oligomers). The various organic peroxides can be used singly or in a blend of two or more of different half-life activity to take advantage of a changing temperature profile which may be used to finish (completely cure) the article (e.g., a printed 3D article).

### Methods of Using the Inventive Photocurable Compositions

The initiator combinations described herein may be suitably used as components of compositions that are to be subjected to curing by means of free radical polymerization, in particular curing initiated by exposure to radiation. In various embodiments, the inventive initiator combinations are employed in combination with one or more types of organic compounds that are able to be cured by free radical polymerization (e.g., (meth)acrylates and other such photocurable ethylenically unsaturated compounds).

End use applications for such photocurable compositions include, but are not limited to, inks, coatings, adhesives, 3D printing resins, molding resins, sealants and the like.

Cured compositions prepared from photocurable compositions in accordance with the present invention may be used, for example, in three-dimensional articles (wherein the three-dimensional article may consist essentially of or consist of the cured composition), coated articles (wherein a substrate is coated with one or more layers of the cured composition), laminated or adhered articles (wherein a first component of the article is laminated or adhered to a second component by means of the cured composition), or printed articles (wherein graphics or the like are imprinted on a substrate, such as a paper, plastic or metal substrate, using the cured composition).

Curing of the inventive photocurable compositions may be carried out by any suitable method, such as free radical polymerization initiated by exposure to a suitable source of radiation (e.g., ultraviolet (UV) radiation). Prior to curing, the photocurable composition may be applied to a substrate surface in any known conventional manner, for example, by spraying, knife coating, roller coating, casting, drum coating, dipping, and the like and combinations thereof. Indirect application using a transfer process may also be used. A substrate may be any commercially relevant substrate, such as a high surface energy substrate or a low surface energy substrate, such as a metal substrate or plastic substrate, respectively. The substrates may comprise metal, paper, cardboard, glass, thermoplastics such as polyolefins, polycarbonate, acrylonitrile butadiene styrene (ABS), and blends thereof, composites, wood, leather and combinations thereof. When used as an adhesive, the composition may be placed between two substrates and then cured, the cured photocurable composition thereby bonding the substrates together.

Curing may be accelerated or facilitated by supplying energy to the composition, such as by heating the composition and/or by exposing the composition to a radiation source, such as visible or UV light, infrared radiation, and/or electron beam radiation. Thus, the cured composition may be deemed the reaction product of the photocurable composition, formed by curing.

A plurality of layers of a photocurable composition in accordance with the present invention may be applied to a substrate surface; the plurality of layers may be simultaneously cured (by exposure to a single dose of radiation, for example) or each layer may be successively cured before application of an additional layer of the photocurable composition (which may be the same as or different from the photocurable composition used to form the preceding layer(s)).

The initiator combinations and photocurable compositions containing such initiator combinations described herein are especially useful in 3D printing resin formulations, that is, compositions intended for use in manufacturing three dimensional articles using 3D printing techniques. Such three dimensional articles may be free-standing/self-supporting and may consist essentially of or consist of a photocurable composition in accordance with the present invention that has been cured. The three-dimensional article may also be a composite, comprising at least one component consisting essentially of or consisting of a cured photocurable composition as previously mentioned as well as at least one additional component comprised of one or more materials other than such a cured photocurable composition (for example, a metal component or a thermoplastic component).

The photocurable compositions of the present invention may be adapted for use in any of the 3D printing techniques known in the art including, for example, stereolithography (SLA), digital light projection/processing (DLP), and multi jet printing.

A method of making a three-dimensional article using photocurable compositions in accordance with the present invention may comprise the steps of:
a) coating a first layer of a photocurable composition in accordance with the present invention onto a surface;
b) at least partially curing the first layer to provide a cured first layer;
c) coating a second layer of the photocurable composition onto the cured first layer;
d) at least partially curing the second layer to provide a cured second layer adhered to the cured first layer; and
e) repeating steps c) and d) a desired number of times to build up the three-dimensional article.

Although the curing steps may be carried out by any suitable means, which will in some cases be dependent upon the components present in the composition, in certain embodiments of the invention the curing is accomplished by exposing the layer to be cured to an effective amount of ultraviolet radiation.

In various embodiments, the present invention also provides a process comprising the steps of:
a) coating a first layer of a photocurable composition in accordance with the present invention and in liquid form onto a surface;
b) exposing the first layer imagewise to ultraviolet radiation to form a first exposed imaged cross-section, wherein the ultraviolet radiation is of sufficient intensity and duration to cause at least partial curing (e.g., at least about 80% or at least about 90% curing) of the layer in the exposed areas;
c) coating an additional layer of the photocurable composition onto the previously exposed imaged cross-section;
d) exposing the additional layer imagewise to ultraviolet radiation to form an additional imaged cross-section, wherein the ultraviolet radiation is of sufficient intensity and duration to cause at least partial curing (e.g., at least about 80% or at least about 90% curing) of the additional layer in the exposed areas and to cause adhesion of the additional layer to the previously exposed imaged cross-section;
e) repeating steps c) and d) a desired number of times to build up the three-dimensional article.

Following the completion of the assembly of the three-dimensional article utilizing the above-described procedures, in certain aspects of the invention the article is subjected to a further curing step involving heating of the article. In such a post-photocuring step, the article is heated to a temperature effective to cause activation of one or more of the peroxides present in the polymeric matrix created in the photocuring step(s). That is, thermal activation of the peroxide(s) is achieved, wherein the peroxide(s) may decompose to generate free radicals. Such free radicals may assist further cure (by, for example, crosslinking) the polymeric matrix, thereby improving its physical properties as compared to those attained in the absence of such a heating step. The temperature at which the article is heated in order to accomplish the desired degree of further curing will depend upon many factors, including, for example, the type(s) and amount(s) of peroxide present, the presence or absence of accelerators which can assist in accelerating the rate of peroxide decomposition or the temperature at which such decomposition begins to occur, the type(s) and amount(s) of residual reactive compounds (e.g., compounds containing ethylenicall unsaturated functional groups capable of reacting via free radical mechanisms), and so forth. Typically, however, the article may be heated at a temperature of from about 100° C. to about 250° C. (preferably not more than about 225° C. or not more than about 200° C.) for a period of time of from about 1 minute to about 6 hours, depending upon the peroxide(s) chosen, the heating temperature selected, the type of monomers and/or oligomers used to create the 3D printed article and the economic and part quality needs of the manufacturing operation. The heating may be carried out in stages or steps; for example, the article may be heated at an initial temperature for a desired period of time and then heated at one or more higher temperatures for an additional period of time. Ramped heating methods may also be employed, wherein the article is subjected to heating under conditions where, for example, the temperature is continuously increased over a period of time.

While not wishing to limit any type of manufacturing operation which may be used in accordance with the present invention, in some cases the time limiting factor might be the printing of a certain number of articles, whereas a multitude of the printed articles could be placed into a large hot air oven for long heat treatment times at lower temperatures. In other cases, the heat treatment could be the immediate next critical step of the operation wherein the total residence time for heat treatment would be the main consideration and thus shorter heat treatment times at higher temperatures would be selected, using microwave, infra-red or laser light heating as well as hot air heating.

The heating of the 3D printed article may be carried out by any suitable means or technique such as, for example, microwave heating, laser light heating, infra-red light heating, ultrasonic energy, hot air heating (e.g., hot air electric heating, hot air gas heating), or other such processes. The article may also be heated by immersing it in a heated liquid (preferably, a liquid that does not dissolve or otherwise degrade the 3D printed article), such as a hot water bath, a hot silicone oil bath, a hot mineral oil bath, or a molten salt bath.

In another embodiment of the invention, the 3D printed article is not subjected to a post-photocuring heating step. Instead, the photocurable composition used to prepare the 3D printed article contains one or more photo-releasable bases of the sort previously described, whereby during photocuring of the photocurable composition the photo-releasable base undergoes a reaction triggered by exposure to radiation to release at least one base which functions as an accelerant for the peroxide(s) present in the photocurable composition. The photo-releasable base(s) and peroxide(s) may be selected such that effective decomposition of the peroxide(s) takes place at ambient temperature, leading to the desired degree of curing of the 3D printed article due to activation of the peroxide(s), thereby avoiding the need to heat the article in order to initiate peroxide composition. In other embodiments of the invention, however, one or more photo-releasable bases are present in the photocurable composition and the 3D printed article thereby obtained is additionally subjected to heating after photocuring of the article.

In various advantageous embodiments of the invention, the conditions employed during the curing step(s) are effective to provide a finished article containing less than 10%, less than 5%, less than 2%, less than 1%, less than 0.5% less than 0.1% or even 0.01% by weight unreacted curable compound.

### EXAMPLES

All of the Examples are prophetic.

### Hardness Testing Method

Final cured articles are tested for hardness using ASTM D2240 which can cover Shore D and Shore A (among other tests). Shore D is used for harder plastics and rubbers, and Shore A for somewhat softer plastics and rubbers. On occasion, depending upon the level of cure, one may have to change from Shore D to Shore A in order to get a proper measurement. In the examples below, measurement with Shore D is attempted. However, if the need arises, Shore A will be used (as is indicated in the testing).

### Example 1 (t-Amyl Type Monoperoxycarbonate Peroxide)

In this example, the use of a select t-amyl type monoperoxycarbonate class of peroxide is demonstrated, specifically Luperox® TAEC whose chemical name is t-amylperoxy-2-ethylhexyl monoperoxycarbonate. It is used at low levels and produces a 3D printed finished part that results in low residual monomer content and by visual inspection has low color after a post-curing step at 130° C. for one hour in a hot air oven.

Materials:

UV-Photoinitiator: Ciba® Irgacure® 819 (Phenylbis(2,4,6-trimethylbenzoyl)phosphine oxide) CAS#162881-26-7 (structure is provided below). It is also known as Photoinitiator 819 or “BAPO” and has a UV Absorption (nm) range of 295-370 nm UV lasers and 390-405 nm UV LED light.

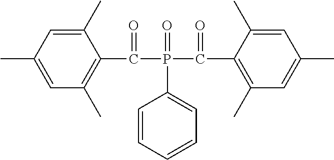

Sartomer® SR-150 (Ethoxylated Bisphenol a Dimethacrylate)

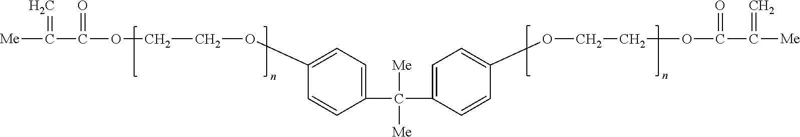

### Resin Formulations in 3D Printer Testing for Example 1

SR-150 (ethoxylated bisphenol A dimethacrylate, a product of Sartomer, Exton, Pa.) whose structure is provided above, is used in a 3D printing composition where 1.0 parts of Irgacure® 819 is present with and without an organic peroxide. The preferred peroxide, a t-amyl type monoperoxycarbonate type peroxide (Luperox® TAEC) is used at a concentration of 0.15 phr (parts by weight per one-hundred parts of resin/monomer). A t-butyl peroxide is also run using this formulation (Luperox® TBEC) and evaluated on an equal active oxygen basis to Luperox® TAEC, as per the teachings of the present invention. Using a UV curing 3D printer, three different acrylic articles are made and labeled #1, #2 and #3 as described below. The parts of each component in the resin formulations are in parts by weight.

A 3D Article Labeled #1 is Printed Using the Following Formulation:
100.00 parts of Sartomer SR-150 monomer (ethoxylated bisphenol A dimethacrylate)
1.00 parts of Irgacure® 819 (phenylbis(2,4,6-trimethylbenzoyl)phosphine oxide)
0.25 part of Luperox® TAEC (92% assay) (t-amylperoxy-2-ethylhexyl monoperoxycarbonate.

A 3D Article Labeled #2 is Minted Using the Following Formulation:
100.00 parts of Sartomer SR-150 monomer (ethoxylated bisphenol A dimethacrylate)
1.00 parts of Irgacure® 819 (Phenylbis(2,4,6-trimethylbenzoyl)phosphine oxide)
0.229 parts of Luperox® TBEC (95% assay) (t-butylperoxy-2-ethylhexyl monoperoxycarbonate), equal in active oxygen to Luperox® TAEC. Luperox® TBEC is a t-butyl type peroxide.

A 3D Article Labeled #3 is Printed Using the Following Formulation (without Peroxide:
100.00 parts of Sartomer SR-150 monomer (ethoxylated bisphenol A dimethacrylate)
1.00 parts of Irgacure® 819 (Phenylbis(2,4,6-trimethylbenzoyl)phosphine oxide)
No organic peroxide is used in this formulation.

The 3D article #3 is placed in a sealed glass jar. The two remaining 3D printed articles labeled #1 and #2 which contained organic peroxide in the formulation are placed in a hot air oven set at 140° C. for 16 minutes. The articles are removed from the oven after 16 minutes and placed in sealed glass jars. Article #3 is not placed in the oven as it contains no peroxide.

All three 3D printed articles in the glass jars are then analyzed for % residual Sartomer SR-150 monomer. Article #3 has a high residual monomer level, Article #2 has a medium residual monomer level and Article #1 (in accordance with the present invention) made using Luperox® TAEC has a low residual monomer level.

Achieving a low residual monomer is important not only from a product safety (leachable) point of view, but also from a mechanical and possibly odor issues. Residual monomer can reduce the hardness, modulus or harm the durability of the final part.

The 3D printed parts are also tested for hardness after all required heat treatment as described above. Article #3 is not placed in the oven as it does not contain any peroxide. Article #3 is the softest, Article #2 is medium hard but Article #1 made with Luperox® TAEC (in accordance with the invention) is the hardest of the three parts as measured by the Shore D hardness test.

In this example, Luperox® TAEC and Luperox® TBEC are compared on an equal active oxygen basis, as described herein previously. In this way, both peroxides are compared on an equal peroxide (—OO—) group basis, which corrects for the number of peroxide groups and the peroxide molecular weight and % assay. The use of Luperox® TAEC followed by the heat treatment to decompose this peroxide provides a significantly lower residual monomer level compared to the use of Luperox® TBEC and the singular use of a UV photo-initiator.

### Example 2 (t-Amyl Type Dialkyl Peroxide)

In this example, a 50:50 blend of two Sartomer monomers is used (SR-833 and SR-531)

Sartomer® SR-833 (tricyclodecane dimethanol diacrylate) has the structure:

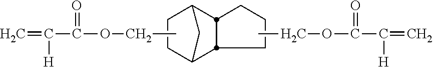

Sartomer® SR-531 (cyclic trimethylolpropane formal acrylate) has the structure:

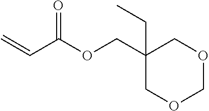

A 3D Article Labeled #1 is Printed Using the Following Formulation:
50.00 parts of Sartomer® SR-833 (tricyclodecane dimethanol diacrylate)
50.00 parts of Sartomer® SR-531 (cyclic trimethylolpropane formal acrylate)
   1.50 parts of Irgacure® 819 (Phenylbis(2,4,6-trimethylbenzoyl)phosphine oxide)
   0.35 parts of Luperox® DTA (96% assay) (di-t-amyl peroxide), a preferred t-amyl type dialkyl peroxide initiator used in the practice of the present invention.

A 3D Article Labeled #2 is Printed Using the Following Formulation:
50.00 parts of Sartomer® SR-833
50.00 parts of Sartomer® SR-531
1.50 parts of Irgacure® 819
0.28 part of Luperox® DI (98.5%) (di-t-butyl peroxide), using equal active oxygen to Luperox® DTA. Luperox® DI is a t-butyl type dialkyl peroxide.

A 3D Article Labeled #3 is Printed Using the Following Formulation (without Peroxide):
50.00 parts of Sartomer) SR-833
50.00 parts of Sartomer® SR-531
   1.50 parts of Irgacure® 819
No organic peroxide is used in this solution

The printed Article #1 and Article #2 that contained peroxide are placed in an oven at 170° C. for 25 minutes. All three parts are tested for % residual monomer. Article #3 has a high residual monomer level, Article #2 has a medium residual monomer level and Article #1 made using Luperox® DTA (a preferred t-amyl type peroxide) in accordance with the present invention has a low residual monomer level. The 3D printed parts are also tested for hardness after all required heat treatment as described above is completed. Article #3 is not placed in the oven as there is no peroxide used to create the part. Article #3 is the softest, Article #2 is medium hard but Article #1 made with Luperox® DTA is the hardest of the three parts as measured by the Shore D hardness test. Luperox® DTA and Luperox® DI are compared on an equal active oxygen basis, which means equal amounts of active peroxide (—OO—) groups, which corrects for molecular weight, % assay and any differences in number of peroxide groups in the molecule.

### Example 3 (t-Amyl Type Diperoxyketal Peroxide)

A high molecular weight diacrylate monomer (Sartomer® SR9003B), whose chemical name is propoxylated neopentylglycol diacrylate, is blended 50:50 on a weight basis with Sartomer® CN9007 (an aliphatic polyether urethane acrylate oligomer)

### Diacrylate Monomer; Sartomer® SR9003B Structure

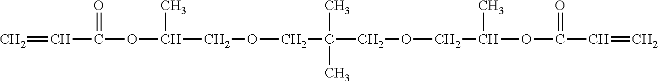 [SMILES: C=CC(=O)OC(C)COCC(C)(C)COCC(C)OC(=O)C=C]

In addition to the UV initiator Irgacure® 819, this example also includes a second UV initiator: Lambson Speedcure® BEM which is a blend of benzophenone+2-methyl benzophenone+4-methyl benzophenone photoinitiators.

A 3D Article Labeled #1 is Printed Using the Following Formulation:
50.00 parts of Sartomer® SR9003B
50.00 parts of Sartomer CN9007
   2.00 parts of Lambson Speedcure® BEM (a benzophenone blend described above)
   0.50 parts of Irgacure® 819 (phenylbis(2,4,6-trimethylbenzoyl)phosphine oxide)
   0.30 parts of Luperox® 531M80 (80% assay) (1,1-di-t-amylperoxy cyclohexane), a preferred t-amyl type diperoxyketal peroxide initiator used in the practice of the present invention.

A 3D Article Labeled #2 is Printed Using the Following Formulation:
50.00 parts of Sartomer® SR9003B
50.00 parts of Sartomer® CN9007
   2.00 parts of Lambson Speedcure® BEM (a benzophenone blend described above)
   0.50 parts of Irgacure® 819 (P\phenylbis(2,4,6-trimethylbenzoyl)phosphine oxide)
   0.27 parts of Luperox® 331M80 (80% assay) (1,1-di-t-butylperoxy cyclohexane), a t-butyl type diperoxyketal peroxide initiator, evaluated on an equal oxygen basis compared to Luperox® 531M80.

A 3D Article Labeled #3 is Printed Using the Following Formulation (without Peroxide):
50.00 parts of Sartomer® SR9003B
50.00 parts of Sartomer® CN9007
   2.00 parts of Lambson Speedcure® BEM (a benzophenone blend described above)
   0.50 parts of Irgacure® 819 (phenylbis(2,4,6-trimethylbenzoyl)phosphine oxide)
No organic peroxide is used in this formulation.

The printed Article #1 and Article #2 that contain peroxide are placed in an oven at 140° C. for 10 minutes. All three parts are tested for % residual monomer. Article #3 has a high residual monomer level, Article #2 has a medium residual monomer level and Article #1 made using Luperox® 531M80 (a preferred t-amyl type peroxide, in accordance with the present invention) has a low residual monomer level. The 3D printed parts are also tested for hardness after all required heat treatment as described above is completed. Article #3 is not placed in the oven as there is no peroxide used to create the part. Article #3 is the softest, Article #2 is medium hard but Article #1 made with Luperox® 531M80 is the hardest of the three parts as measured by the Shore D hardness test and also has a better color (visual inspection) than Article #2. Luperox® 531M80 and Luperox® 331M80 are compared on an equal active oxygen basis, i.e., equal amounts of active peroxide (—OO—) groups, which corrects for molecular weight, % assay and any differences in number of peroxide groups in the molecule.

### Example 4 (t-Amyl Type Hemi-Peroxyketal Peroxide)

A 3D Article Labeled #1 is Printed Using the Following Formulation:
50.00 parts of Sartomer® SR9003B
50.00 parts of Sartomer® CN9007
   2.00 parts of Lambson Speedcure® BEM (a benzophenone blend described above)
   0.50 parts of Irgacure® 819 (phenylbis(2,4,6-trimethylbenzoyl)phosphine oxide)
   0.35 parts of Luperox® V10 (93% assay) (1-t-amylperoxy-1-methoxy cyclohexane), a preferred t-amyl type hemi-peroxyketal peroxide initiator used in the practice of the present invention.

A 3D Article Labeled #2 is Minted Using the Following Formulation:
50.00 parts of Sartomer® SR9003B
50.00 parts of Sartomer® CN9007
   2.00 parts of Lambson Speedcure® BEM (a benzophenone blend described above)
   0.50 parts of Irgacure® 819 (Phenylbis(2,4,6-trimethylbenzoyl)phosphine oxide)
   0.24 parts of Luperox® 231(92% assay) (1,1-di-t-butylperoxy-3,3,5-trimethyl cyclohexane), a t-butyl type diperoxyketal peroxide initiator which is evaluated on an equal oxygen basis compared to Luperox® V10 (93% assay).

A 3D Article Labeled #3 is Printed Using the Following Formulation (without Peroxide):
50.00 parts of Sartomer® SR9003B
50.00 parts of Sartomer CN9007
   2.00 parts of Lambson Speedcure® BEM (a benzophenone blend described above)
   0.50 parts of Irgacure® 819 (phenylbis(2,4,6-trimethylbenzoyl)phosphine oxide)
No organic peroxide is used in this formulation.

The printed Article #1 and Article #2 that contained peroxide are placed in an oven at 135° C. for 10 minutes. All three parts are tested for % residual monomer. Article #3 has a high residual monomer level, Article #2 has a medium residual monomer level and Article #1 made using Luperox® V100 (a preferred t-amyl type peroxide, in accordance with the invention) has a low residual monomer level. The 3D printed parts are also tested for hardness after all required heat treatment as described above is completed. Article #3 is not placed in the oven as there is no peroxide used to create the part. Article #3 is the softest, Article #2 is medium hard but Article #1 made with Luperox® V10 is the hardest of the three parts as measured by the Shore D hardness test and also has a better color (visual inspection) than Article #2. Luperox® V10 and Luperox® 231 are compared on an equal active oxygen basis, i.e., equal amounts of active peroxide (—OO—) groups, which corrects for molecular weight, % assay and any differences in number of peroxide groups in the molecule.

### Example 5 (t-Amyl Type Diperoxyketal Peroxide)

A 3D Article Labeled #1 is Printed Using the Following Formulation:
50.00 parts of Sartomer® SR-833 (tricyclodecane dimethanol diacrylate)
50.00 parts of Sartomer® SR-531 (cyclic trimethylolpropane formal acrylate)
   2.00 parts of Lambson Speedcure® BEM (a benzophenone blend described above)
   0.50 parts of Irgacure® 819 (Phenylbis(2,4,6-trimethylbenzoyl)phosphine oxide)
   0.30 parts of Luperox® 531M80 (80% assay) (1,1-di-t-amylperoxy cyclohexane) a preferred t-amyl type diperoxyketal peroxide initiator used in the practice of the present invention.

A 3D Article Labeled #2 is Printed Using the Following Formulation:
50.00 parts of Sartomer® SR-833 (tricyclodecane dimethanol diacrylate)
50.00 parts of Sartomer SR-531 (cyclic trimethylolpropane formal acrylate)
2.00 parts of Lambson Speedcure® BEM (a benzophenone blend described above)
   0.50 parts of Irgacure® 819 (Phenylbis(2,4,6-trimethylbenzoyl)phosphine oxide)
   0.27 parts of Luperox® 331M80 (80% assay) (1,1-di-t-butylperoxy cyclohexane), a t-butyl type diperoxyketal peroxide initiator evaluated on an equal oxygen basis compared to Luperox® 531M80.

A 3D Article Labeled #3 is Printed Using the Following Formulation (without Peroxide):
50.00 parts of Sartomer SR-833 (tricyclodecane dimethanol diacrylate)
50.00 parts of Sartomer SR-531 (cyclic trimethylolpropane formal acrylate)
2.00 parts of Lambson Speedcure® BEM (a benzophenone blend described above)
   0.50 parts of Irgacure® 819 (Phenylbis(2,4,6-trimethylbenzoyl)phosphine oxide)
No organic peroxide is used in this formulation.

The printed Article #1 and Article #2 that contained peroxide are placed in an oven at 140° C. for 10 minutes. All three parts are tested for % residual monomer. Article #3 has a high residual monomer level, Article #2 has a medium residual monomer level and Article #1 made using Luperox® 531M80 (a preferred t-amyl type peroxide) has a low residual monomer level. The 3D printed parts are also tested for hardness after all required heat treatment as described above is completed. Article #3 is not placed in the oven as there is no peroxide used to create the part. Article #3 is the softest, Article #2 is medium hard but Article #1 made with Luperox® 531M80 is the hardest of the three parts as measured by the Shore D hardness test and also has a better color (visual inspection) than Article #2. Luperox® 531M80 and Luperox® 331M80 are compared on an equal active oxygen basis, i.e., equal amounts of active peroxide (—OO—) groups, which corrects for molecular weight, % assay and any differences in number of peroxide groups in the molecule.

### Example 6 (t-Amyl Type Hemi-Peroxyketal Peroxide)

A 3D Article Labeled #1 is Printed Using the Following Formulation:
50.00 parts of Sartomer® SR-833 (tricyclodecane dimethanol diacrylate)
50.00 parts of Sartomer® SR-531 (cyclic trimethylolpropane formal acrylate)
2.00 parts of Lambson Speedcure® BEM (a benzophenone blend described above)
   0.50 parts of Irgacure® 819 (phenylbis(2,4,6-trimethylbenzoyl)phosphine oxide)
   0.35 parts of Luperox® V10 (93% assay) (1-t-amylperoxy-1-methoxy cyclohexane) a preferred t-amyl type hemi-peroxyketal peroxide initiator used in accordance with the present invention.

A 3D Article Labeled #2 is Printed Using the Following Formulation:
50.00 parts of Sartomer® SR-833 (tricyclodecane dimethanol diacrylate)
50.00 parts of Sartomer® SR-531 (cyclic trimethylolpropane formal acrylate)
2.00 parts of Lambson Speedcure® BEM (a benzophenone blend described above)
   0.50 parts of Irgacure® 819 (phenylbis(2,4,6-trimethylbenzoyl)phosphine oxide)
   0.24 parts of Luperox® 231(92% assay) (1,1-di-t-butylperoxy-3,3,5-trimethyl cyclohexane), a t-butyl type diperoxyketal peroxide initiator evaluated on an equal oxygen basis compared to Luperox® V10 (93% assay).

A 3D Article Labeled #3 is Printed Using the Following Solution without Peroxide
50.00 parts of Sartomer SR-833 (tricyclodecane dimethanol diacrylate)
50.00 parts of Sartomer SR-531 (cyclic trimethylolpropane formal acrylate)
2.00 parts of Lambson Speedcure® BEM (a benzophenone blend described above)
   0.50 parts of Irgacure® 819 (phenylbis(2,4,6-trimethylbenzoyl)phosphine oxide)
No organic peroxide is used in this solution.

The printed Article #1 and Article #2 that contained peroxide are placed in an oven at 135° C. for 10 minutes. All three parts are tested for % residual monomer. Article #3 has a high residual monomer level, Article #2 has a medium residual monomer level and Article #1 made using Luperox® V10 (a preferred t-amyl type peroxide, in accordance with the invention) has a low residual monomer level. The 3D printed parts are also tested for hardness after all required heat treatment as described above is completed. Article #3 is not placed in the oven as there is no peroxide used to create the part. Article #3 is the softest, Article #2 is medium hard but Article #1 made with Luperox® V10 is the hardest of the three parts as measured by the Shore D hardness test and also has a better color (visual inspection) than Article #2. Luperox® V10 and Luperox® 231 are compared on an equal active oxygen basis, i.e., equal amounts of active peroxide (—OO—) groups, which corrects for molecular weight, % assay and any differences in number of peroxide groups in the molecule.

### Example 7 (Unsaturated Peroxide)

A 3D Article Labeled #1 is Printed Using the Following Formulation:
50.00 parts of Sartomer® SR-833 (tricyclodecane dimethanol diacrylate)
50.00 parts of Sartomer® SR-531 (cyclic trimethylolpropane formal acrylate)
2.00 parts of Lambson Speedcure® BEM (a benzophenone blend described above)
   0.50 parts of Irgacure® 819 (phenylbis(2,4,6-trimethylbenzoyl)phosphine oxide)
   0.35 parts of IP-D16 (50% assay) (isopropenyl t-butylperoxy isopropylbenzene), an unsaturated t-butylperoxy type peroxide in accordance with the present invention.

A 3D Article Labeled #2 is Printed Using the Following Formulation:
50.00 parts of Sartomer® SR-833 (tricyclodecane dimethanol diacrylate)
50.00 parts of Sartomer® SR-531 (cyclic trimethylolpropane formal acrylate)
2.00 parts of Lambson Speedcure® BEM (a benzophenone blend described above)
   0.50 parts of Irgacure® 819 (Phenylbis(2,4,6-trimethylbenzoyl)phosphine oxide)
   0.153 parts of Luperox® D16 (96% assay) (t-butyl cumyl peroxide), a conventional t-butyl peroxy type saturated peroxide, evaluated on an equal active oxygen basis to IP-D16 (50% assay).

A 3D Article Labeled #3 is Printed Using the Following Formulation (without Peroxide):
50.00 parts of Sartomer® SR-833 (tricyclodecane dimethanol diacrylate)
50.00 parts of Sartomer® SR-531 (cyclic trimethylolpropane formal acrylate)
2.00 parts of Lambson Speedcure® BEM (a benzophenone blend described above)
   0.50 parts of Irgacure® 819 (Phenylbis(2,4,6-trimethylbenzoyl)phosphine oxide)
No organic peroxide is used in this formulation.

This example demonstrates the advantage of using an unsaturated organic peroxide. All of the 3D printed articles are first printed on the same day, then allowed to sit on the bench-top at room temperature (about 20° C.) for one week. The IP-D16 peroxide has been unexpectedly covalently bonded into the 3D printed article using the UV initiators. However, the standard (saturated) organic peroxide is mobile and some of it can migrate to the surface of the 3D part and evaporate.

After the one week period, the printed Article #1 and Article #2 that contained peroxide are placed in an oven at 175° C. for 10 minutes. All three parts are tested for % residual monomer. Article #3 has a high residual monomer level, Article #2 has a medium residual monomer level and Article #1 made using IP-D6 (50% assay) (isopropenyl t-butylperoxy isopropylbenzene), an unsaturated peroxide used in accordance with the present invention, has a low residual monomer level.

The 3D printed parts are also tested for hardness after all required heat treatment as described above is completed. Article #3 is not placed in the oven as there is no peroxide used to create the part. Article #3 is the softest, Article #2 is medium hard but Article #1 made with IP-D16 (50% assay) (isopropenyl t-butylperoxy isopropylbenzene) is the hardest of the three parts as measured by the Shore D hardness test. IP-D16 (50% assay) (isopropenyl t-butylperoxy isopropylbenzene) and Luperox® D-16 are compared on an equal active oxygen basis, i.e., equal amounts of active peroxide (—OO—) groups, which corrects for molecular weight, % assay and any differences in number of peroxide groups in the molecule.

### Example 8 (t-Amyl Type Peroxyester Peroxide)

A 3D Article Labeled #1 is Printed Using the Following Formulation:
50.00 parts of Sartomer® SR-833 (tricyclodecane dimethanol diacrylate)
50.00 parts of Sartomer® SR-531 (cyclic trimethylolpropane formal acrylate)
2.00 parts of Lambson Speedcure® BEM (a benzophenone blend described above)
   0.50 parts of Irgacure® 819 (phenylbis(2,4,6-trimethylbenzoyl)phosphine oxide)
   0.35 parts of Luperox® 555M60 (60% assay) (t-amylperoxyacetate), a t-amyl type peroxyester peroxide in accordance with the present invention.

A 3D Article Labeled #2 is Printed Using the Following Formulation:
50.00 parts of Sartomer® SR-833 (tricyclodecane dimethanol diacrylate)
50.00 parts of Sartomer® SR-531 (cyclic trimethylolpropane formal acrylate)
2.00 parts of Lambson Speedcure® BEM (a benzophenone blend described above)
   0.50 parts of Irgacure® 819 (phenylbis(2,4,6-trimethylbenzoyl)phosphine oxide)
   0.25 parts of Luperox® 7M75 (75% assay) (t-butylperoxyacetate), a t-butylperoxy type peroxide, evaluated on an equal active oxygen basis compared to Luperox® 555M60

A 3D Article Labeled #3 is Printed Using the Following Formulation (without Peroxide):
50.00 parts of Sartomer® SR-833 (tricyclodecane dimethanol diacrylate)
50.00 parts of Sartomer® SR-531 (cyclic trimethylolpropane formal acrylate)
2.00 parts of Lambson Speedcure® BEM (a benzophenone blend described above)
   0.50 parts of Irgacure® 819 (phenylbis(2,4,6-trimethylbenzoyl)phosphine oxide)
No organic peroxide is used in this formulation.

The 3D printed Article #1 and Article #2 that contained peroxide are placed in an oven at 175° C. for 10 minutes. All three parts are tested for % residual monomer. Article #3 has a high residual monomer level, Article #2 has a medium residual monomer level and Article #1 made using Luperox® 555M60 (t-amylperoxyacetate), a t-amylperoxy type peroxyester peroxide used in accordance with the present invention, has a low residual monomer level.

The 3D printed parts are also tested for hardness after all required heat treatment as described above. Article #3 is not placed in the oven as there is no peroxide used to create the part. Article #3 is the softest, Article #2 is medium hard but Article #1 made with Luperox® 555M60 (t-amylperoxyacetate) is the hardest of the three parts as measured by the Shore D hardness test. Luperox® 555M60 (t-amylperoxyacetate) and Luperox® 7M75 (t-butylperoxy-acetate) are compared on an equal active oxygen basis, i.e., equal amounts of active peroxide (—OO—) groups, which corrects for molecular weight, % assay and any differences in number of peroxide groups in the molecule.

### Example 9 (a Blend of Two t-Amyl Type Peroxides: Diperoxyketal and Monoperoxycarbonate)

A 3D Article Labeled #1 is Printed Using the Following Formulation:
50.00 parts of Sartomer® SR-833 (tricyclodecane dimethanol diacrylate)
50.00 parts of Sartomer® SR-531 (cyclic trimethylolpropane formal acrylate)
   2.00 parts of Lambson Speedcure® BEM (a benzophenone blend described above)
   0.50 parts of Irgacure® 819 (Phenylbis(2,4,6-trimethylbenzoyl)phosphine oxide)
   0.15 parts of Luperox® 531M80 (80% assay) (1,1-di-t-amylperoxy cyclohexane), a preferred t-amyl type diperoxyketal peroxide initiator in accordance with the present invention.
   0.15 part of Luperox® TAEC (92% assay) (t-amylperoxy-2-ethylhexyl monoperoxy carbonate), a preferred t-amyl type monoperoxycarbonate peroxide initiator in accordance with the present invention.

A 3D Article Labeled #2 is Printed Using the Following Formulation:
50.00 parts of Sartomer® SR-833 (tricyclodecane dimethanol diacrylate)
50.00 parts of Sartomer® SR-531 (cyclic trimethylolpropane formal acrylate)
2.00 parts of Lambson Speedcure® BEM (a benzophenone blend described above)
   0.50 parts of Irgacure® 819 (phenylbis(2,4,6-trimethylbenzoyl)phosphine oxide)
   0.135 parts of Luperox® 331M80 (80% assay) (1,1-di-t-butylperoxy cyclohexane), a t-butyl type diperoxyketal peroxide initiator which is evaluated on an equal oxygen basis compared to Luperox® 531M80.
   0.137 parts of Luperox® TBEC (95% assay) (t-butylperoxy-2-ethylhexyl monoperoxycarbonate), used on an equal active oxygen basis to Luperox® TAEC. Luperox® TBEC is a t-butyl type peroxide.

A 3D Article Labeled #3 is Printed Using the Following Formulation (without Peroxide):
50.00 parts of Sartomer® SR-833 (tricyclodecane dimethanol diacrylate)
50.00 parts of Sartomer® SR-531 (cyclic trimethylolpropane formal acrylate)
2.00 parts of Lambson Speedcure® BEM (a benzophenone blend described above)
   0.50 parts of Irgacure® 819 (Phenylbis(2,4,6-trimethylbenzoyl)phosphine oxide)
No organic peroxide is used in this formulation

The 3D printed Article #1 and Article #2 that contained peroxide are placed in an oven at 160° C. for 12 minutes. All three parts are tested for % residual monomer. Article #3 has a high residual monomer level, Article #2 has a medium residual monomer level which is much improved over Article #3 and Article #1 made using a blend of two different t-amyl peroxides (Luperox® 531M80 and Luperox® TAEC has a lower residual monomer level.

The 3D printed parts are also tested for hardness after all required heat treatment as described above. Article #3 is not placed in the oven as there is no peroxide used to create the part. Article #3 is the softest, Article #2 is medium hard but Article #1 made using a novel blend of two different t-amyl peroxides: Luperox® 531M80 and Luperox® TAEC is the hardest of the three parts as measured by the Shore D hardness test. Luperox® 531M80 and Luperox® TAEC are compared on an equal active oxygen basis to Luperox® 331M80 and Luperox® TBEC, respectively. Thus, the two t-amyl peroxides are compared based upon equal amounts of active peroxide (—OO—) groups to their corresponding t-butyl peroxide counterparts.

### Example 10 (Blend of a t-Amyl Type Peroxide Used in Combination with Preferred Non-t-Amyl Polyoligomeric Peroxide)

A 3D Article Labeled #1 is Printed Using the Following Formulation:
50.00 parts of Sartomer® SR-833 (tricyclodecane dimethanol diacrylate)
50.00 parts of Sartomer® SR-531 (cyclic trimethylolpropane formal acrylate)
2.00 parts of Lambson Speedcure® BEM (a benzophenone blend described above)
   0.50 parts of Irgacure® 819 (phenylbis(2,4,6-trimethylbenzoyl)phosphine oxide)
0.15 parts of Luperox® 531M80 (80% assay) (1,1-di-t-amylperoxy cyclohexane), a preferred t-amyl type diperoxyketal peroxide
   0.137 parts of Luperox® TBEC (95% assay) (t-butylperoxy-2-ethylhexyl monoperoxycarbonate)

A 3D Article Labeled #2 is Printed Using the Following Formulation:
50.00 parts of Sartomer® SR-833 (tricyclodecane dimethanol diacrylate)
50.00 parts of Sartomer® SR-531 (cyclic trimethylolpropane formal acrylate)
2.00 parts of Lambson Speedcure® BEM (a benzophenone blend described above)
0.50 parts of Irgacure® 819 (phenylbis(2,4,6-trimethylbenzoyl)phosphine oxide)
0.15 parts of Luperox® 531 M80 (80% assay) (1,1-di-t-amylperoxy cyclohexane), a preferred t-amyl type diperoxyketal peroxide
   0.25 part of Luperox® JWEB™ 50 (polyether poly-t-butyl peroxycarbonate) with a 50% assay, which is a preferred non t-amyl type monoperoxycarbonate peroxide initiator in accordance with the present invention evaluated equal active oxygen to 0.137 parts of Luperox® TBEC (95% assay).

A 3D Article Labeled #3 is Printed Using the Following Formulation (without Peroxide):
50.00 parts of Sartomer® SR-833 (tricyclodecane dimethanol diacrylate)
50.00 parts of Sartomer® SR-531 (cyclic trimethylolpropane formal acrylate)
2.00 parts of Lambson Speedcure® BEM (a benzophenone blend described above)
   0.50 parts of Irgacure® 819 (Phenylbis(2,4,6-trimethylbenzoyl)phosphine oxide)
No organic peroxide is used in this formulation
   In this experiment, the 3D printed articles were not immediately place in the oven. All the 3D printed articles were stored on a benchtop at 70° F. uncovered for 24 hours.
   After 24 hours of storage, the 3D printed Article #1 and Article #2 that contained peroxide are placed in an oven at 160° C. for 12 minutes. Article #3 without peroxide was not placed in the oven.
   All three printed parts are tested for % residual monomer. Article #3 has a high residual monomer level, Article #1 has a medium residual monomer level which is much improved over Article #3 and Article #2 made using a blend of a preferred t-amyl peroxide and a preferred non-t-amyl polyoligomer peroxide (Luperox® 531M80 and Luperox® JWEB™50 respectively) in accordance with the present invention) has the lowest residual monomer level.
   In summary, the use of the branched polyoligomer t-butyl type peroxide Luperox® JWEB™50 in combination with Luperox® 531M80 a preferred t-amyl type peroxide provided a more robust cure system versus the use of Luperox® 531M80 and Luperox® TBEC for 3D printed articles that are stored prior to oven curing.

1. A composition, comprising:
a) at least one of a photoinitiator or a photo-releasable base; and
b) at least one t-amyl peroxide which is ethylenically saturated or unsaturated.

2. The composition of claim 1, comprising at least one photo-releasable amine.

3. The composition of claim 1, additionally comprising at least one ethylenically saturated or unsaturated peroxide that is different from the t-amyl peroxide of claim 1.

4. The composition of claim 1, wherein the at least one t-amyl peroxide comprises at least one ethylenically unsaturated t-amyl peroxide.

5. The composition of claim 1, wherein the at least one t-amyl peroxide comprises at least one ethylenically saturated t-amyl peroxide.

6. The composition of claim 1, comprising a) at least one photoinitiator, at least one t-amyl peroxide and at least one photo-releasable base; b) at least one photoinitiator, at least one t-amyl peroxide and at least one ethylenically unsaturated peroxide; c) at least one photoinitiator and at least one t-amyl peroxide; d) at least one photo-releasable base and at least one t-amyl peroxide; or e) at least one photoinitiator, at least one photo-releasable base, at least one t-amyl peroxide and at least one ethylenically unsaturated peroxide.

7. The composition of claim 1, wherein the composition comprises at least one photoinitiator selected from the group consisting of benzophenone photoinitiators, α-hydroxyketone photoinitiators, α-aminoketone photoinitiators, phosphine oxide photoinitiators, benzoin alkyl ether photoinitiators, benzyl ketal photoinitiators, 4-aroyl-1,3-dioxolane photoinitiators, oxime ester photoinitiators, halomethyltriazine photoinitiators, metallocenes and combinations thereof.

8. The composition of claim 1, wherein the composition comprises at least one t-amyl peroxide selected from the group consisting of hemi-peroxyketals, diperoxyketals, peroxyesters, dialkyl peroxides, hydroperoxides, monoperoxycarbonates and combinations thereof.

9. The composition of claim 1, wherein the composition comprises at least one t-amyl peroxide having a one hour half-life of at least 85° C., at least 90° C., at least 92° C., at least 95° C. or at least 99° C.

10. The composition of claim 1, wherein the composition comprises at least one saturated t-amyl peroxide selected from the group consisting of 1-t-amylperoxy-1-methoxy cyclohexane, 1,1-di-t-amylperoxy cyclohexane, 1,1-di-t-amylperoxy-3,3,5-trimethyl cyclohexane, 2,2-di-t-amyl peroxy butane, 2,2-di-t-amylperoxypropane, OO-t-amyl-O-(2-ethylhexyl) monoperoxycarbonate, OO-t-amyl-O-(2-isopropyl) monoperoxycarbonate, t-amyl peroxyacetate, t-amylperoxy-3,5,5-trimethylhexanoate, di-t-amyl peroxide, t-amyl hydroperoxide, and combinations thereof.

11. The composition of claim 1, wherein the composition comprises at least one photo-releasable amine which releases at least one tertiary amine upon exposure to ultraviolet light.

12. The composition of claim 1, wherein the composition comprises at least one ethylenically unsaturated peroxide.

13. The composition of claim 1, wherein the ethylenically saturated peroxide comprises an organic peroxide branched oligomer comprising at least three peroxide groups and having the structure D wherein the sum of W, X, Y and Z is 6 or 7:

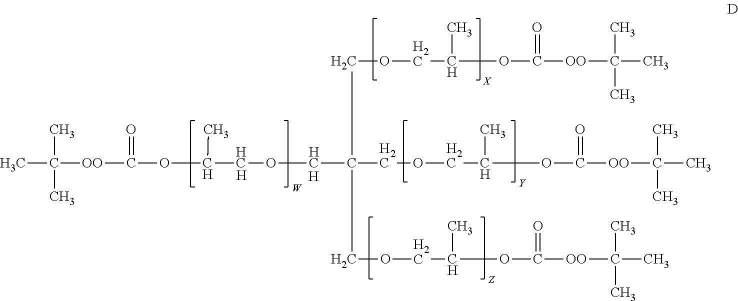

14. The composition of claim 1, wherein the organic peroxide is present in an amount of 0.1 to 5% by weight, based on the total composition weight.

15. The composition of claim 1, comprising at least one ethylenically unsaturated organic peroxide comprising at least one moiety selected from the group consisting of isopropenyl moieties, (meth)acrylate moieties, fumarate moieties, maleate moieties, and itaconate moieties.

16. A photocurable composition, comprising the composition of claim 1 and at least one photocurable compound.

17. The photocurable composition of claim 16, wherein the at least one photocurable compound is selected from the group consisting of ethylenically unsaturated monomers and oligomers and combinations thereof.

18. The photocurable composition of claim 16, wherein the at least one photocurable compound is selected from the group consisting of (meth)acrylate-functionalized monomers and oligomers and combinations thereof.

19. A cured composition obtained by curing of the photocurable composition of claim 13.

20. A method of making a three dimensional article, comprising the steps of:
a) at least partially curing a first layer of a curable composition in accordance with claim 1 on a surface to provide at least a partially cured first layer;
b) at least partially curing a second layer of a curable composition in accordance with claim 1 onto the at least partially cured first layer to provide at least a partially cured second layer adhered to or adjacent to the at least partially cured first layer; and
c) repeating step b) a desired number of times to build up the three-dimensional article.

21. The method of claim 20, wherein the curing steps are performed by exposing each layer of the photocurable composition to radiation.

22. The method of claim 20, comprising an additional step of heating the three-dimensional article.

23. A three-dimensional article obtained by the method of claim 20.

24. (canceled)
